(19) United States
(12) Patent Application Publication
(10) Pub. No.: US 2024/0429154 A1
(43) Pub. Date: Dec. 26, 2024

(54) SEMICONDUCTOR DEVICE

(71) Applicant: ROHM CO., LTD., Kyoto-shi (JP)

(72) Inventors: Tomoki FUJIMURA, Kyoto-shi (JP); Kohei TANIKAWA, Kyoto-shi (JP); Tomohiro YASUNISHI, Kyoto-shi (JP)

(21) Appl. No.: 18/823,982

(22) Filed: Sep. 4, 2024

Related U.S. Application Data
(63) Continuation of application No. PCT/JP2023/010950, filed on Mar. 20, 2023.

(30) Foreign Application Priority Data
Mar. 30, 2022 (JP) 2022-055492

(51) Int. Cl. H01L 23/498; H01L 23/00; H01L 23/31; H01L 25/07

(52) U.S. Cl. CPC H01L 23/49838; H01L 23/3107; H01L 23/49811; H01L 24/40; H01L 25/072; H01L 2224/4005; H01L 2224/40137; H01L 2224/40227; H01L 2924/13091; H01L 2924/3511

(57) ABSTRACT

A semiconductor device includes: a supporting substrate including a first conductive part and a second conductive part; a plurality of first semiconductor elements mounted on the first conductive part and each having a switching function; a plurality of second semiconductor elements mounted on the second conductive part and each having a switching function; a first terminal protruding toward the first side in an x direction relative to the first conductive part; a first conductive member electrically connecting the plurality of first semiconductor elements and the second conductive part; a second conductive member electrically connecting the plurality of second semiconductor elements and the first conductive part; and a sealing resin covering the plurality of first semiconductor elements, the plurality of second semiconductor elements, the first conductive member, the second conductive member, a portion of the supporting substrate, and a portion of the first terminal. The first terminal and the second conductive member are integrally formed.

### TECHNICAL FIELD

The present disclosure relates to semiconductor devices.

### BACKGROUND ART

Conventional semiconductor devices incorporating power switching elements, such as metal-oxide-semiconductor field-effect transistors (MOSFETs) and insulated gate bipolar transistors (IGBTs), are known. Such semiconductor devices are used in various electronic devices, ranging from industrial devices to home appliances and information terminals, or even to vehicle-mount devices. JP-A-2021-190505 discloses a conventional semiconductor device (power module). The semiconductor device disclosed in JP-A-2021-190505 includes a semiconductor element and a supporting substrate (ceramic substrate). In one example, the semiconductor element is an IGBT made of silicon (Si). The supporting substrate supports the semiconductor element. The supporting substrate includes an insulating base and conductive layers stacked on the opposite sides of the base. The base is made of, for example a ceramic material. The conductive layers are made of, for example, copper (Cu), and one of the conductive layers is bonded to the semiconductor element. The semiconductor element is covered with, for example, the sealing resin.

### BRIEF DESCRIPTION OF THE DRAWINGS

FIG. 1 is a perspective view of a semiconductor device according to a first embodiment of the present disclosure.

FIG. 2 is a perspective view showing important portions of the semiconductor device according to the first embodiment of the present disclosure.

FIG. 3 is a perspective view showing important portions of the semiconductor device according to the first embodiment of the present disclosure.

FIG. 4 is a plan view of the semiconductor device according to the first embodiment of the present disclosure.

FIG. 5 is a plan view showing important portions of the semiconductor device according to the first embodiment of the present disclosure.

FIG. 6 is a side view showing important portions of the semiconductor device according to the first embodiment of the present disclosure.

FIG. 7 is an enlarged plan view showing important portions of the semiconductor device according to the first embodiment of the present disclosure.

FIG. 8 is a plan view showing important portions of the semiconductor device according to the first embodiment of the present disclosure.

FIG. 9 is a plan view showing important portions of the semiconductor device according to the first embodiment of the present disclosure.

FIG. 10 is a side view of the semiconductor device according to the first embodiment of the present disclosure.

FIG. 11 is a bottom view of the semiconductor device according to the first embodiment of the present disclosure.

FIG. 12 is a sectional view taken along line XII-XII in FIG. 5.

FIG. 13 is a sectional view taken along line XIII-XIII in FIG. 5.

FIG. 14 is an enlarged sectional view showing important portions of the semiconductor device according to the first embodiment of the present disclosure.

FIG. 15 is an enlarged sectional view showing important portions of the semiconductor device according to the first embodiment of the present disclosure.

FIG. 16 is a sectional view taken along line XVI-XVI in FIG. 5.

FIG. 17 is a sectional view taken along line XVII-XVII in FIG. 5.

FIG. 18 is a sectional view taken along line XVIII-XVIII in FIG. 5.

FIG. 19 is a sectional view taken along line XIX-XIX in FIG. 5.

FIG. 20 is a sectional view taken along line XX-XX in FIG. 5.

FIG. 21 is a perspective view of a second conductive member of the semiconductor device according to the first embodiment of the present disclosure.

FIG. 22 is a plan view of the second conductive member of the semiconductor device according to the first embodiment of the present disclosure.

FIG. 23 is a front view of the second conductive member of the semiconductor device according to the first embodiment of the present disclosure.

FIG. 24 is an enlarged front view of the second conductive member of the semiconductor device according to the first embodiment of the present disclosure.

FIG. 25 is a side view of the second conductive member of the semiconductor device according to the first embodiment of the present disclosure.

FIG. 26 is a sectional view showing a first variation of the semiconductor device according to the first embodiment of the present disclosure.

FIG. 27 is a sectional view showing the first variation of the semiconductor device according to the first embodiment of the present disclosure.

FIG. 28 is a vehicle incorporating a semiconductor device according to the present disclosure.

### DETAILED DESCRIPTION OF EMBODIMENTS

The following describes preferred embodiments of the present disclosure in detail with reference to the drawings.

In the present disclosure, the terms such as “first”, “second”, “third”, and so on are used merely as labels and are not intended to impose a specific order or sequence on the items modified by the terms.

In the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a portion of the object B”. Still further, “A surface A faces in a direction B (or faces a first side or a second side in the direction B) is not limited, unless otherwise specifically noted, to the situation where the surface A forms an angle of 90° with the direction B but includes the situation where the surface A is inclined with respect to the direction B.

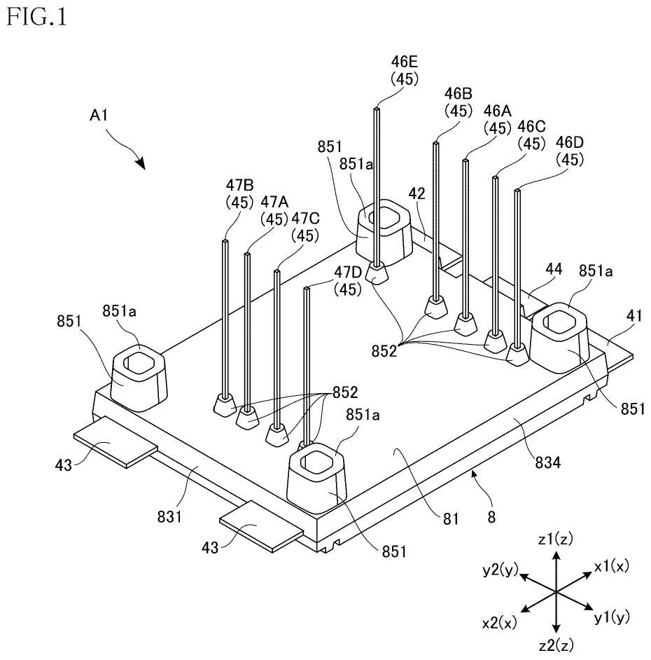

FIGS. 1 to 25 show a semiconductor device according to a first embodiment of the present disclosure. The semiconductor device A1 of the present embodiment includes a plurality of first semiconductor elements 10A, a plurality of second semiconductor elements 10B, a supporting substrate 3, a first terminal 41, a second terminal 42, a plurality of third terminals 43, a fourth terminal 44, a plurality of control terminals 45, a control terminal support 48, a first conductive member 5, a second conductive member 6, and a sealing resin 8.

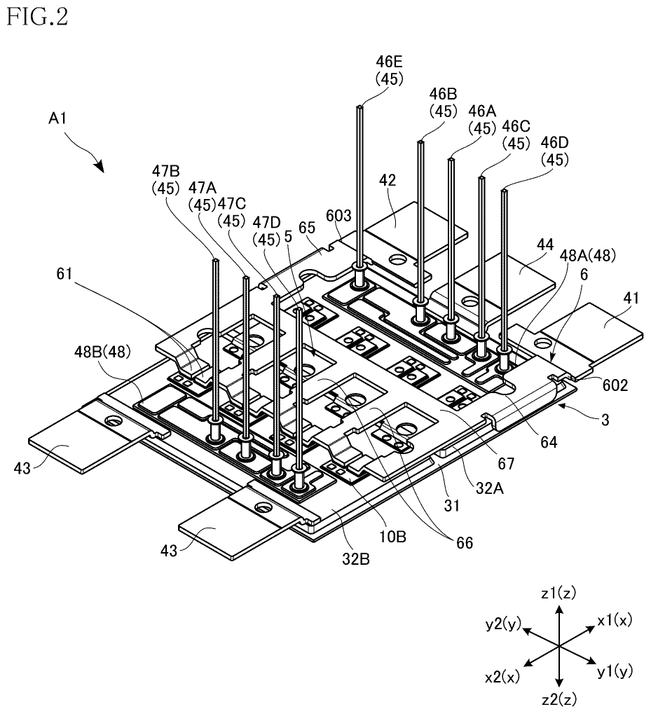

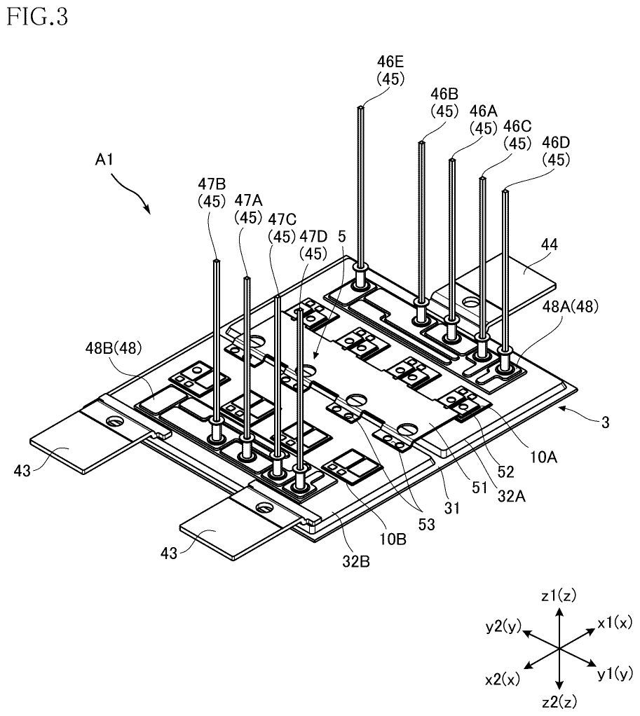

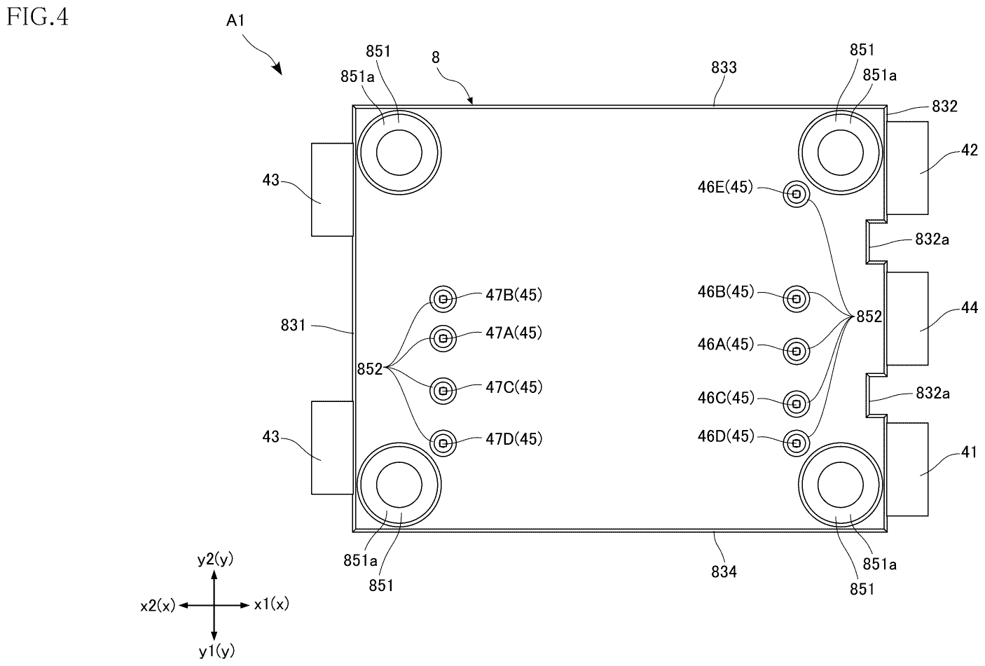

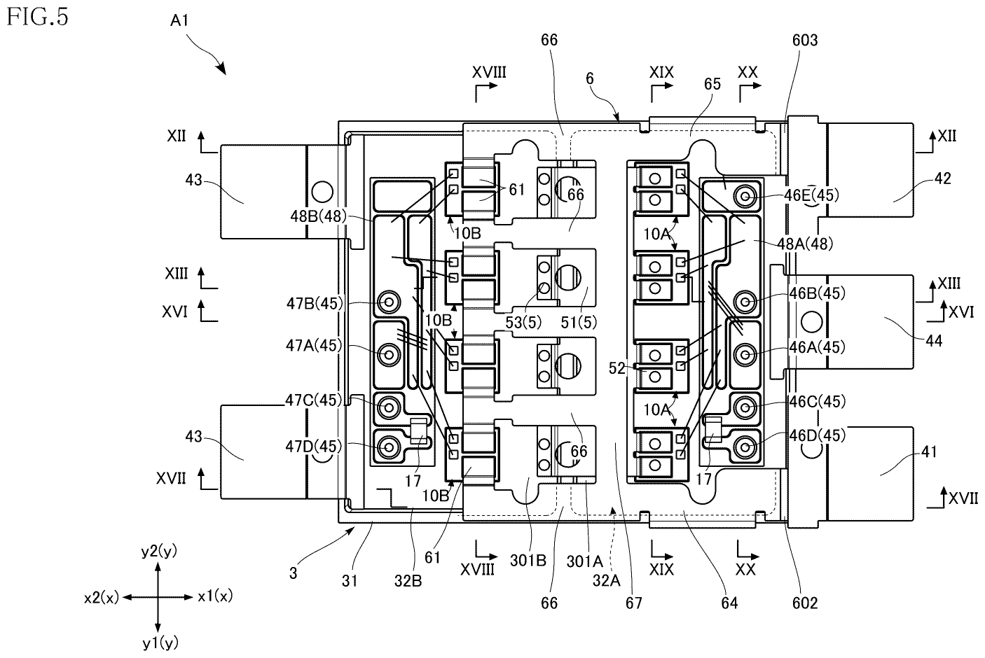

FIG. 1 is a perspective view of the semiconductor device A1. FIGS. 2 and 3 are perspective views showing important portions of the semiconductor device A1. FIG. 4 is a plan view of the semiconductor device A1. FIG. 5 is a plan view showing important portions of the semiconductor device A1.

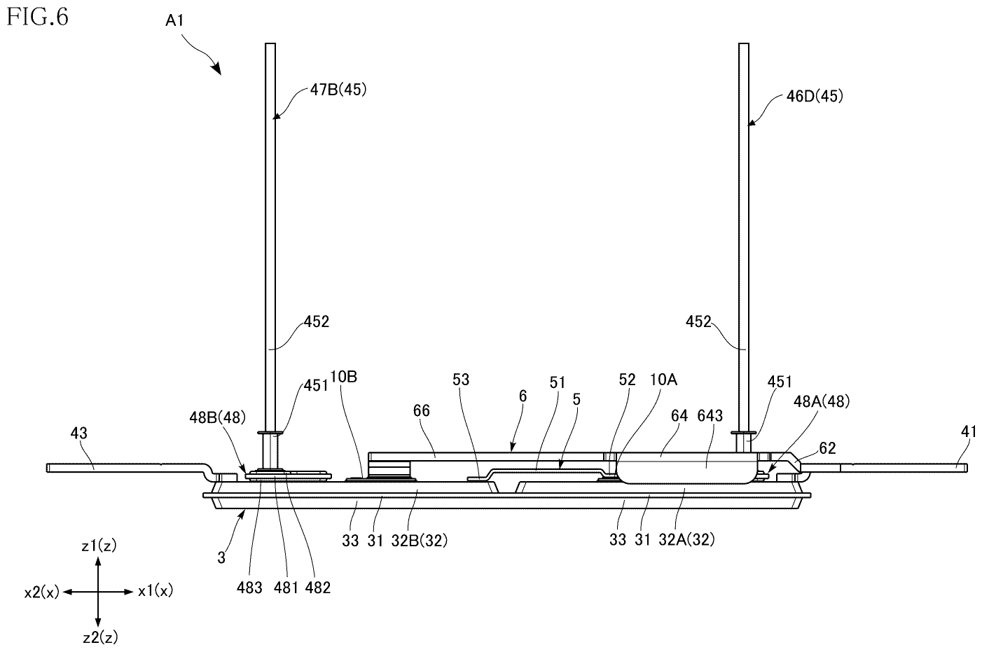

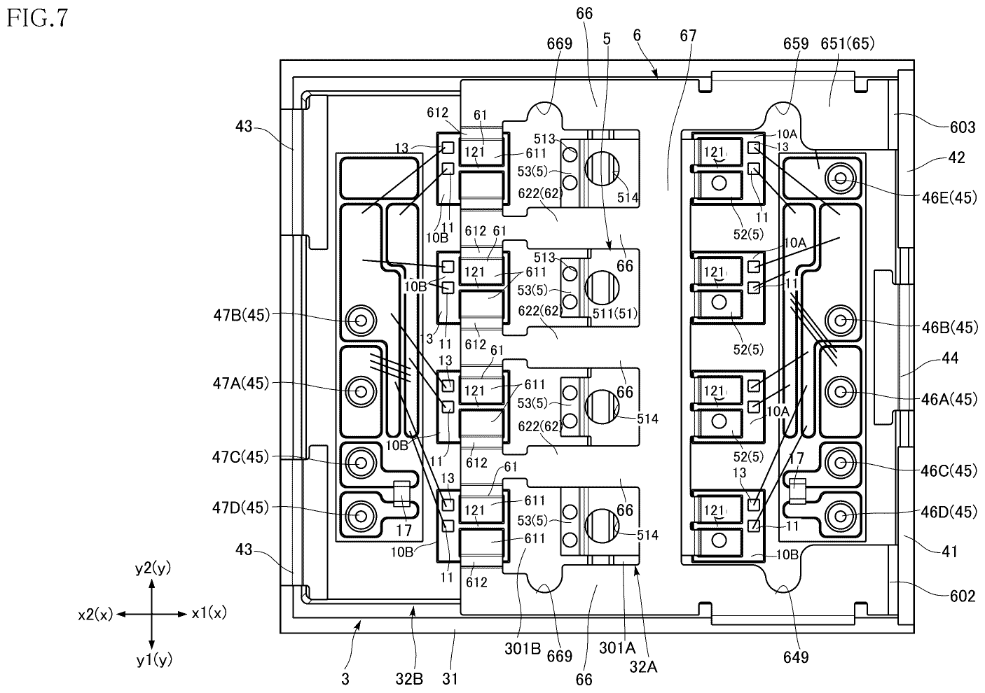

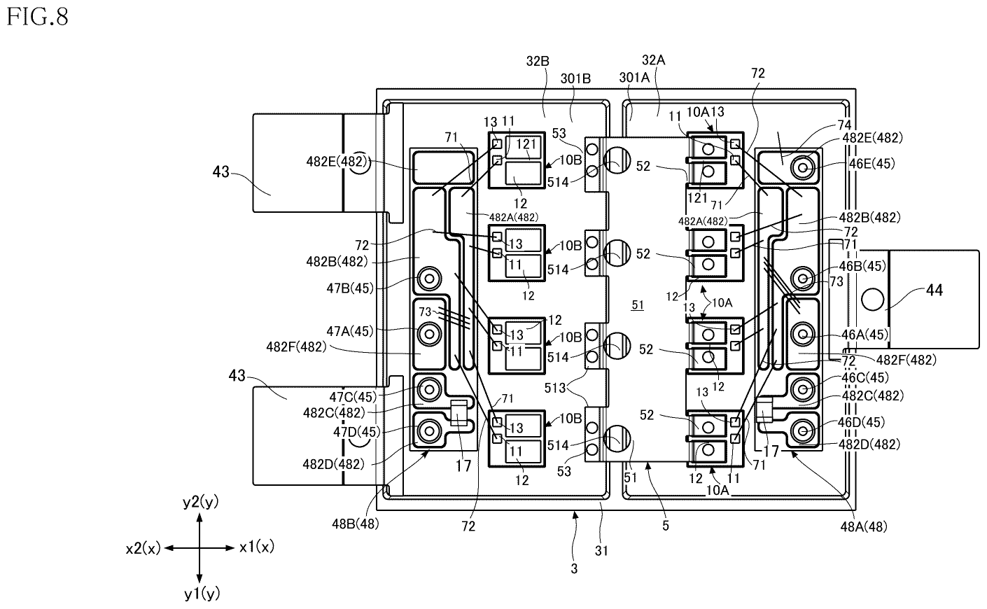

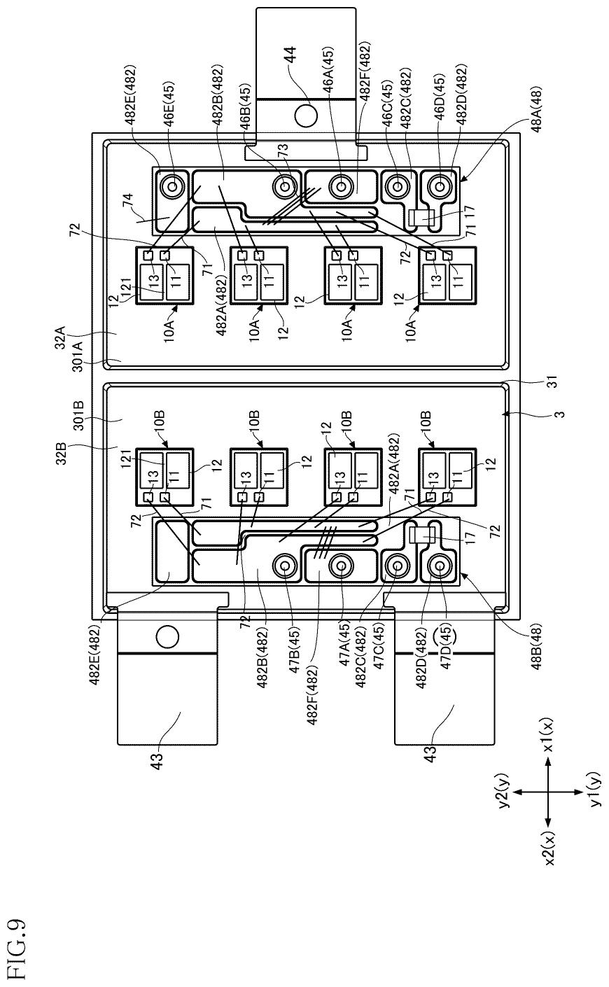

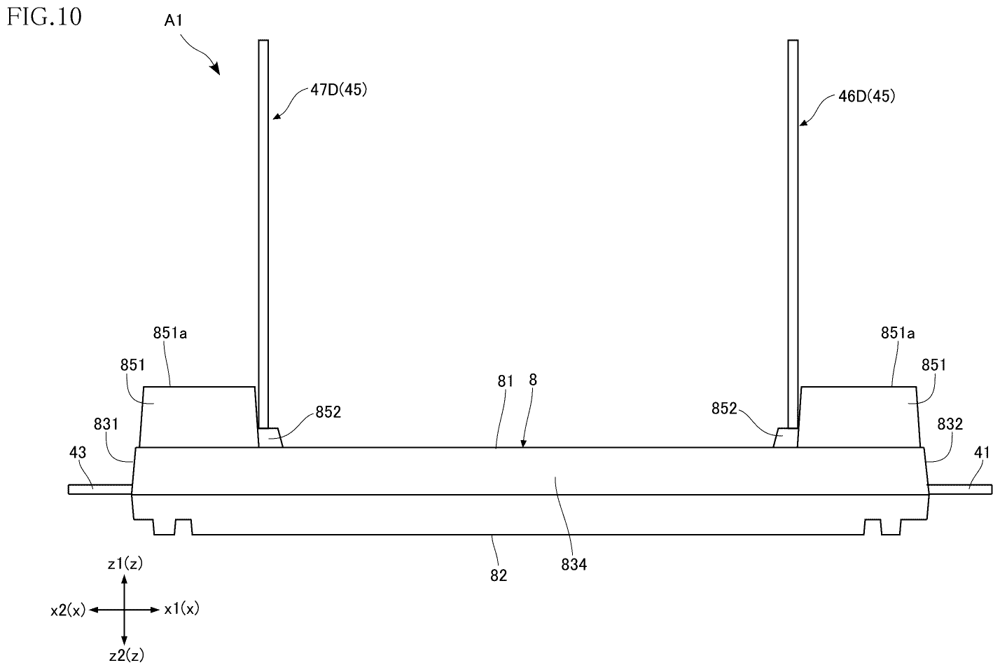

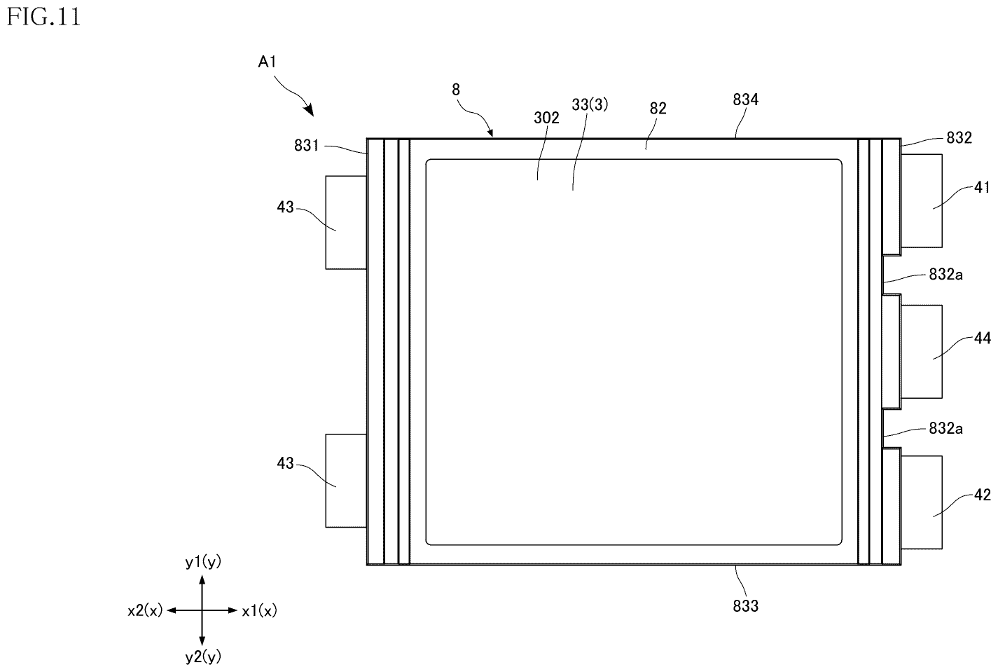

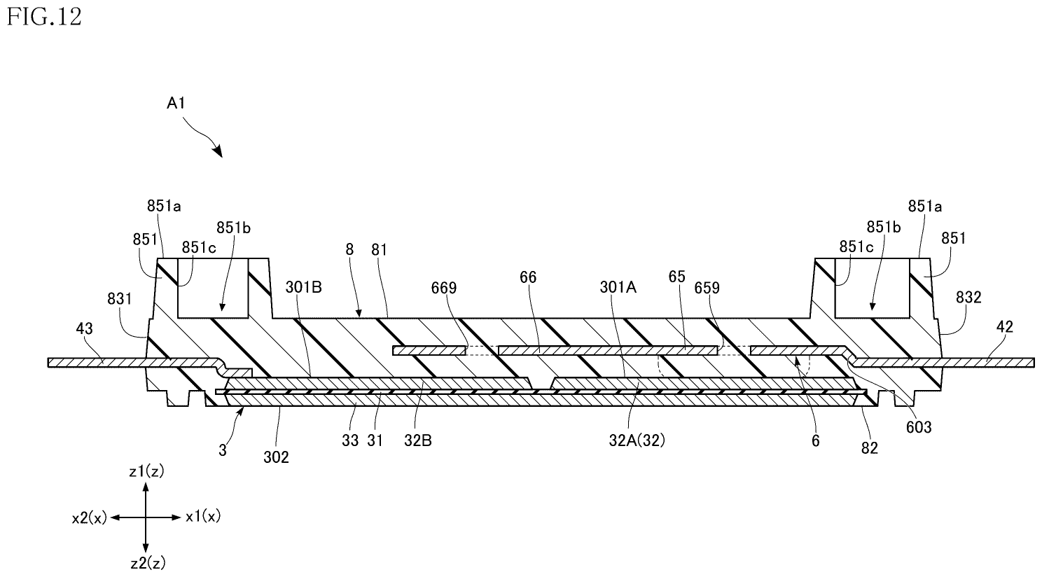

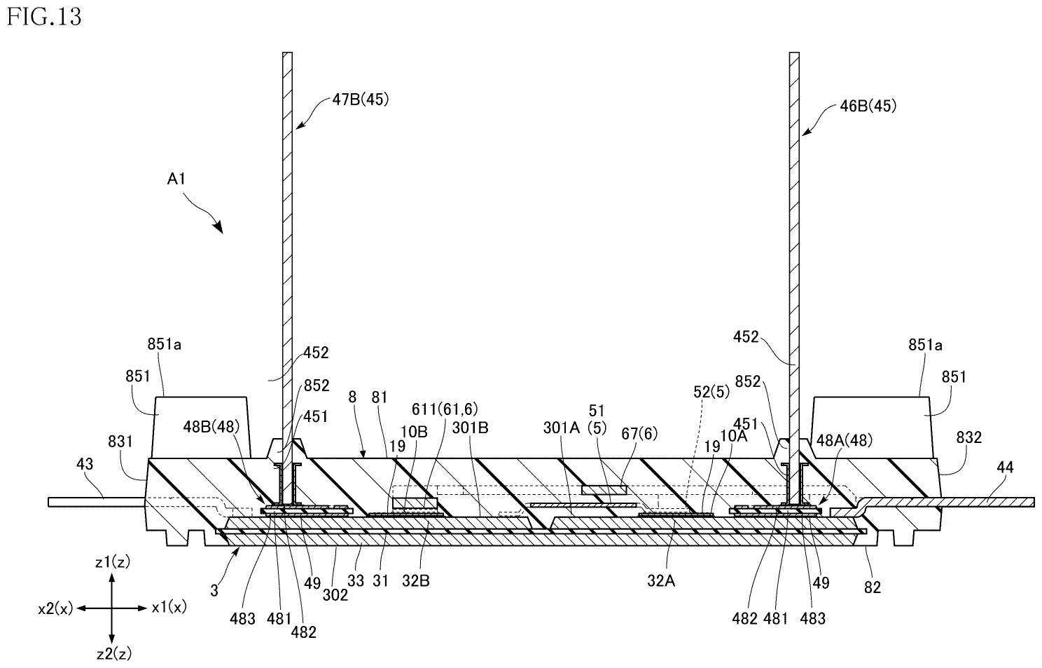

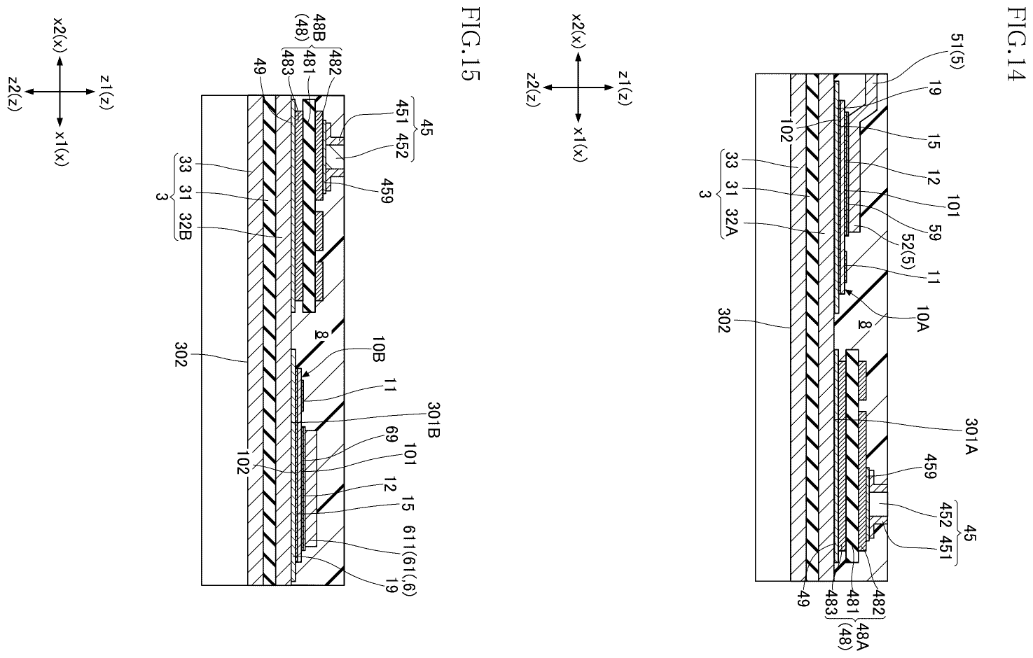

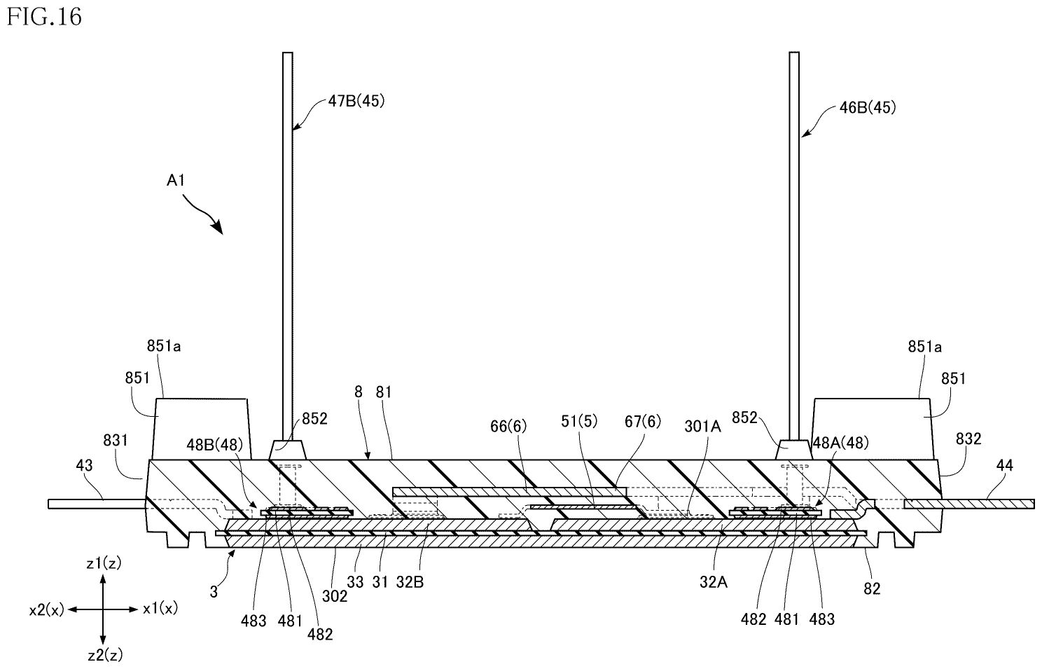

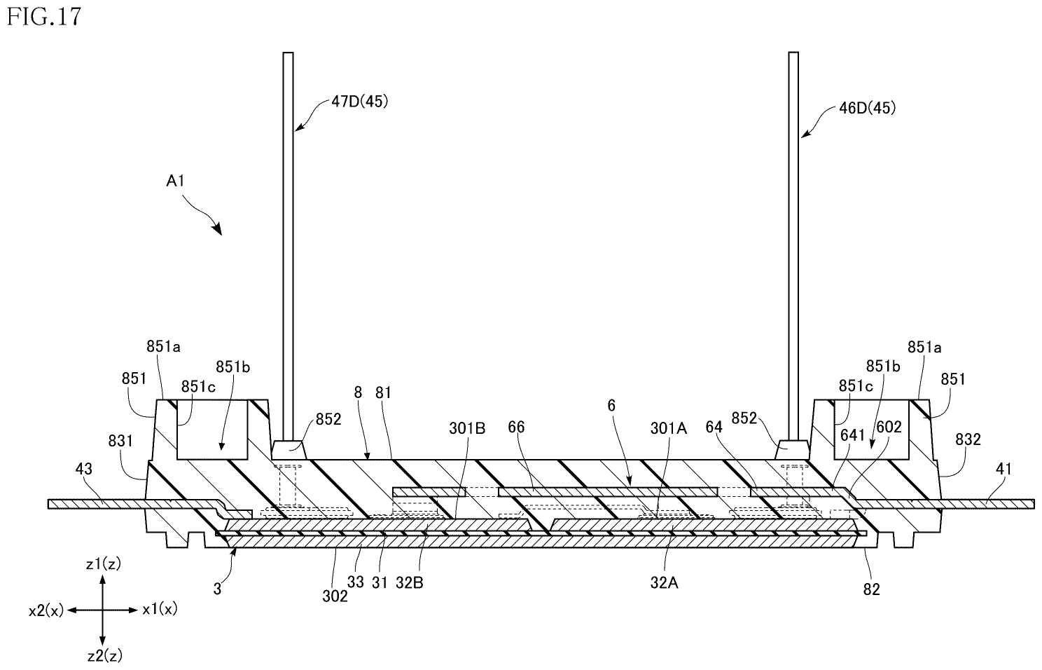

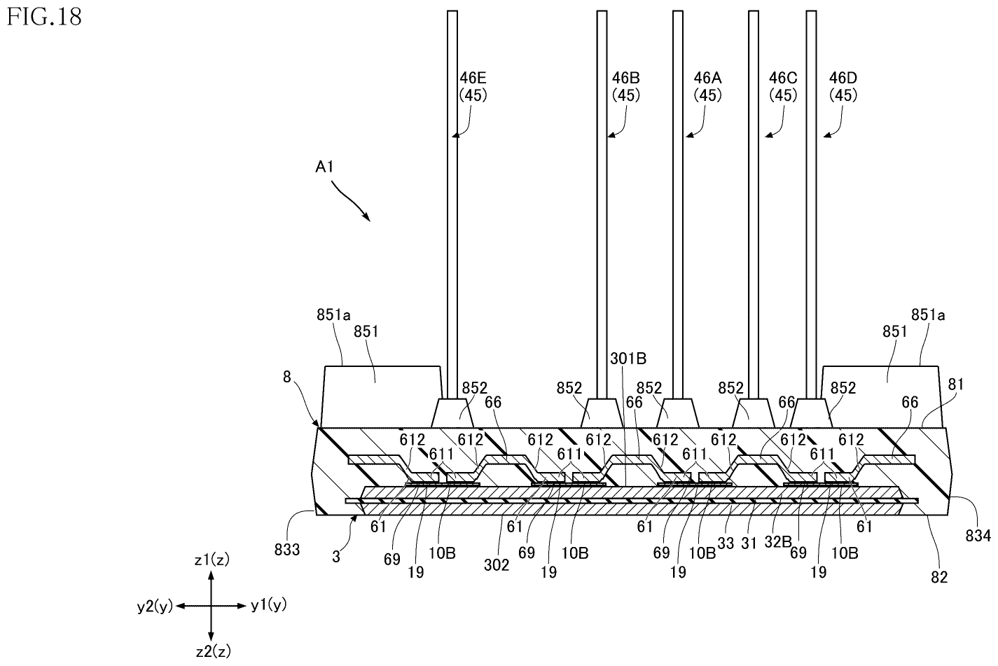

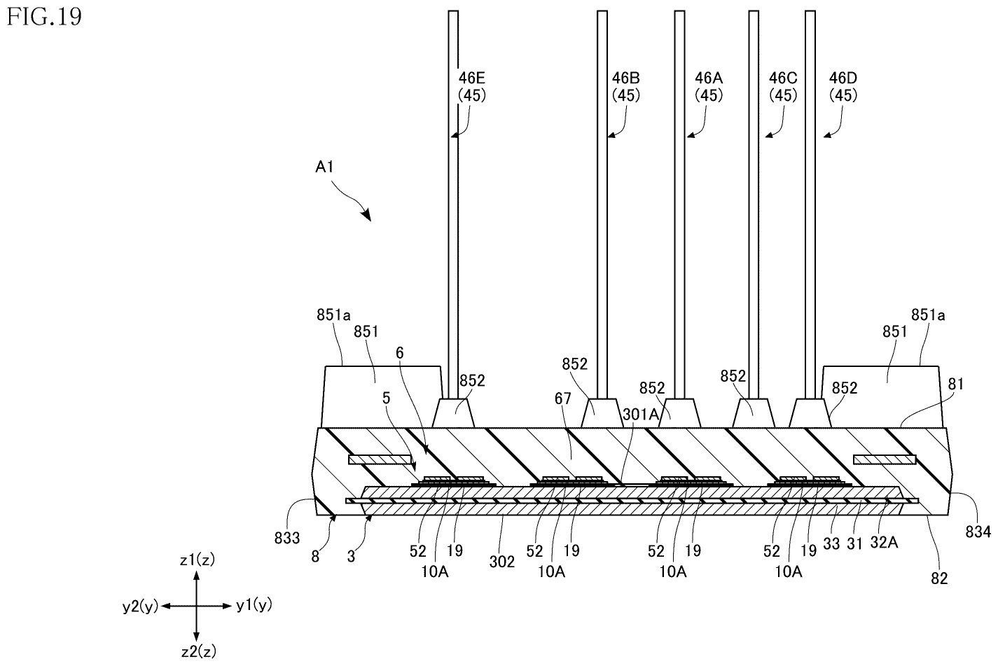

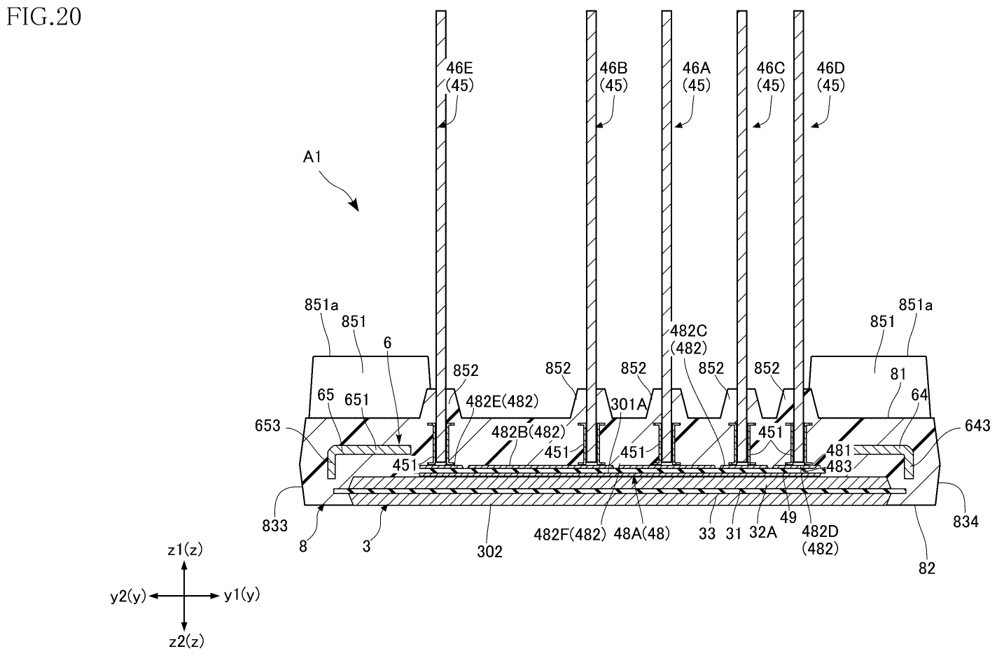

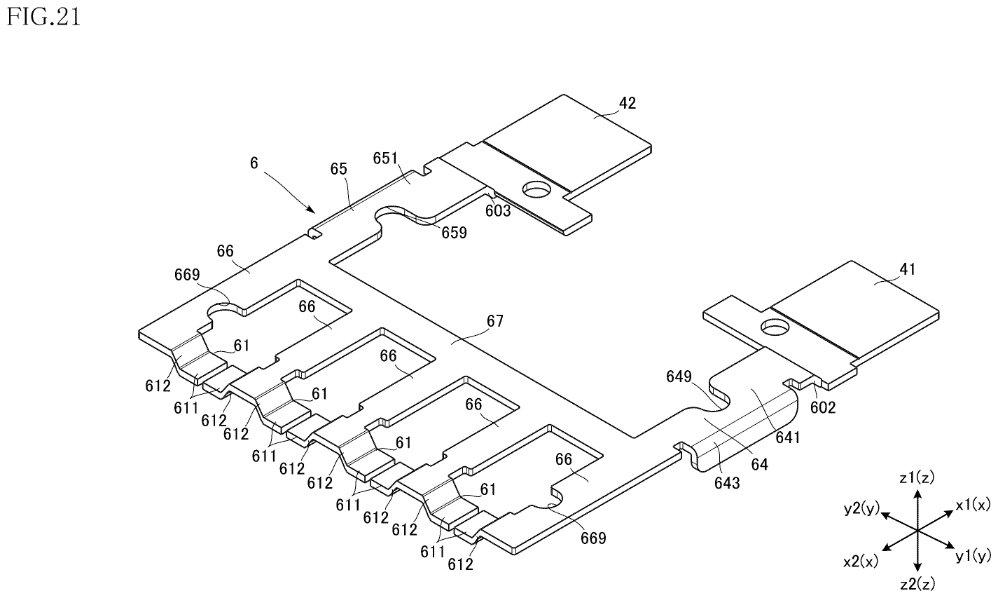

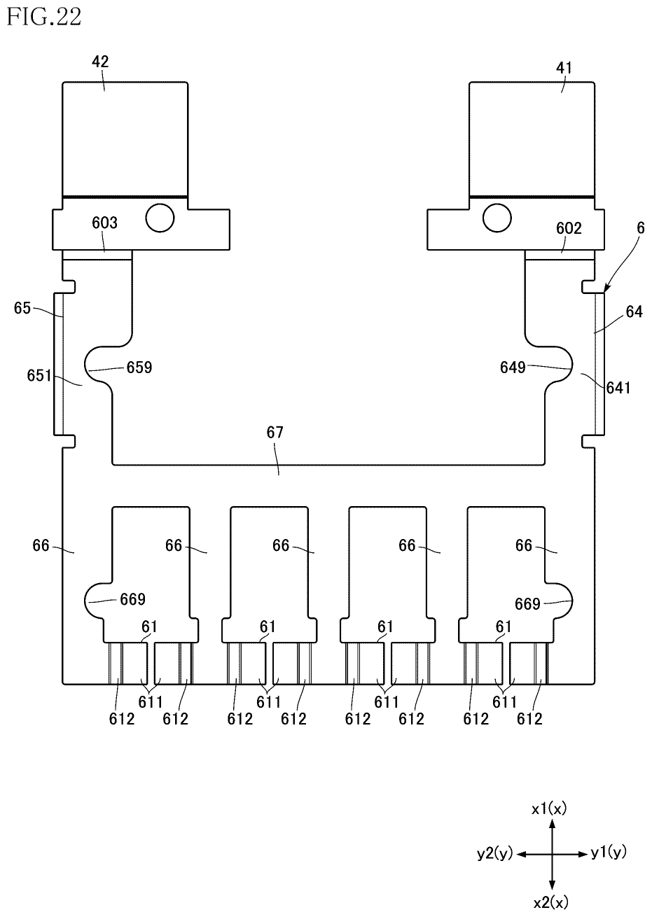

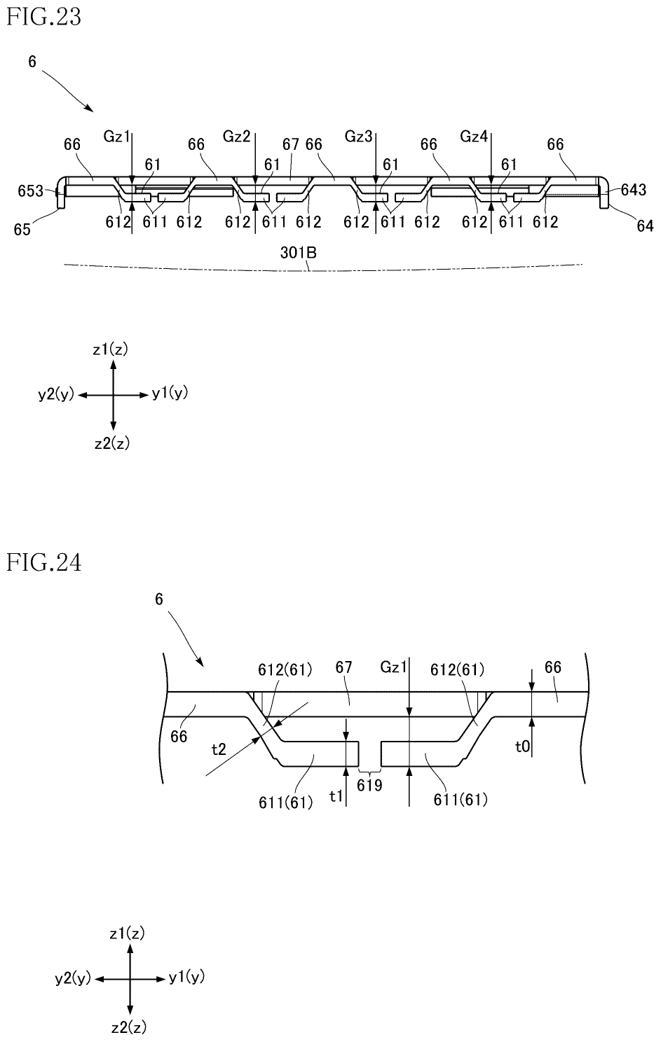

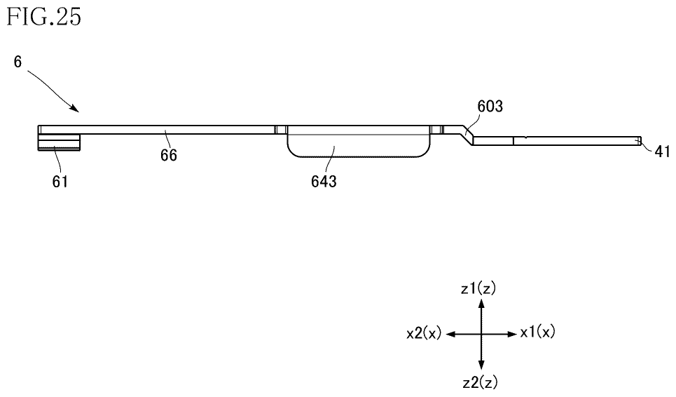

FIG. 6 is a side view showing important portions of the semiconductor device A1. FIG. 7 is an enlarged plan view showing important portions of the semiconductor device A1. FIGS. 8 and 9 are plan views showing important portions of the semiconductor device A1. FIG. 10 is a side view of the semiconductor device A1. FIG. 11 is a bottom view of the semiconductor device A1. FIG. 12 is a sectional view taken along line XII-XII in FIG. 5. FIG. 13 is a sectional view taken along line XIII-XIII in FIG. 5. FIGS. 14 and 15 are enlarged sectional views showing important portions of the semiconductor device A1. FIG. 16 is a sectional view taken along line XVI-XVI in FIG. 5. FIG. 17 is a sectional view taken along line XVII-XVII in FIG. 5. FIG. 18 is a sectional view taken along line XVIII-XVIII in FIG. 5. FIG. 19 is a sectional view taken along line XIX-XIX in FIG. 5. FIG. 20 is a sectional view taken along line XX-XX in FIG. 5. FIG. 21 is a perspective view of the second conductive member 6 of the semiconductor device A1. FIG. 22 is a plan view of the second conductive member 6 of the semiconductor device A1. FIG. 23 is a front view of the second conductive member 6 of the semiconductor device A1. FIG. 24 is an enlarged front view showing important portions of the second conductive member of the semiconductor device A1. FIG. 25 is a side view of the second conductive member 6 of the semiconductor device A1.

In these figures, the z direction is an example of the thickness direction of the present disclosure, the x direction is an example of the first direction of the present disclosure, and the y direction is an example of the second direction of the present disclosure. In addition, a first side in the x direction is defined as the x1 side in the x direction, and a second side in the x direction is defined as the x2 side in the x direction. Also, a first side in the y direction is defined as the y1 side in the y direction, and a second side in the y direction is defined as the y2 side in the y direction. Also, a first side in the z direction is defined as the z1 side in the z direction, and a second side in the z direction is defined as the z2 side in the z direction.

The first semiconductor elements 10A and the second semiconductor elements 10B are electronic components integral to the functionality of the semiconductor device A1. The first semiconductor elements 10A and the second semiconductor elements 10B are made of a semiconductor material primarily consisting of silicon carbide (SiC), for example. The semiconductor material is not limited to SiC, and examples include silicon (Si), gallium nitride (GaN), and diamond (C). Each of the first semiconductor elements 10A and the second semiconductor elements 10B may be a power semiconductor chip, such as a metal-oxide semiconductor field-effect transistor (MOSFET) having a switching function. The first semiconductor elements 10A and the second semiconductor elements 10B of the present embodiment are MOSFETs, but this is a non-limiting example. The first semiconductor elements 10A and the second semiconductor elements 10B may be other types of transistors, such as insulated gate bipolar transistors (IGBTs). The first semiconductor elements 10A and the second semiconductor elements 10B are identical elements. The first semiconductor elements 10A and the second semiconductor elements 10B are n-channel MOSFETS. Alternatively, however, the first semiconductor elements 10A and the second semiconductor elements 10B may be p-channel MOSFETS.

As shown in FIGS. 14 and 15, each of the first semiconductor elements 10A and the second semiconductor elements 10B has an element obverse surface 101 and an element reverse surface 102. In each of the first semiconductor elements 10A and the second semiconductor elements 10B, the element obverse surface 101 and the element reverse surface 102 are spaced apart in the z direction. The element obverse surface 101 faces the z1 side in the z direction, and the element reverse surface 102 faces the z2 side in the z direction.

In the present embodiment, the semiconductor device A1 includes four first semiconductor elements 10A and four second semiconductor elements 10B. The numbers of the first semiconductor elements 10A and the second semiconductor elements 10B, however, are not limited to this example, and can be appropriately changed depending on the performance required for the semiconductor device A1. In the example shown in FIGS. 8 and 9, four first semiconductor elements 10A and four second semiconductor element 10B are arranged. In another example, the respective numbers of the first semiconductor elements 10A and the second semiconductor elements 10B may be two or three, or even five or more. In addition, the numbers of the first semiconductor elements 10A and the second semiconductor elements 10B may be the same or different. The numbers of the first semiconductor elements 10A and the second semiconductor elements 10B are determined depending on the current capacity to be handled by the semiconductor device A1.

The semiconductor device A1 is configured as a half-bridge switching circuit, for example. In this case, the first semiconductor elements 10A form an upper arm circuit of the semiconductor device A1, and the second semiconductor elements 10B form a lower arm circuit. In the upper arm circuit, the first semiconductor elements 10A are connected lower in parallel. In the arm circuit, the second semiconductor elements 10B are connected in parallel. Each first semiconductor element 10A is connected in series to a second semiconductor element 10B to form a bridge layer.

As shown in FIGS. 8, 9, and 19 in particular, the first semiconductor elements 10A are mounted on a later-described first conductive part 32A of the supporting substrate 3. In the example shown in FIGS. 8 and 9, the first semiconductor elements 10A are spaced apart in the y direction. The first semiconductor elements 10A are electrically bonded to the first conductive part 32A via a conductive bonding material 19. The first semiconductor elements 10A are bonded to the first conductive part 32A, such that their element reverse surfaces 102 face the first conductive part 32A. Different from the present embodiment, the first semiconductor elements 10A may be mounted on a metal member that is not a part of the substrate, such as a DBC substrate. In this case, the metal member corresponds to the first conductive part of the present disclosure. The metal member may be supported on the first conductive part 32A, for example.

As shown in FIGS. 8, 9, and 18 in particular, the second semiconductor elements 10B are mounted on a later-described second conductive part 32B of the supporting substrate 3. In the example shown in FIGS. 8 and 9, the second semiconductor elements 10B are spaced apart in the y direction. The second semiconductor elements 10B are electrically bonded to the second conductive part 32B via the conductive bonding material 19. The second semiconductor elements 10B are bonded to the second conductive part 32B, such that their element reverse surfaces 102 face the second conductive part 32B. As can be understood from FIG. 9, the first semiconductor elements 10A and the second semiconductor elements 10B overlap with each other as viewed in the x direction, but this overlap is not necessary. Different from the present embodiment, in addition, the second semiconductor elements 10B may be mounted on a metal member that is not a part of the substrate, such as a DBC substrate. In this case, the metal member corresponds to the second conductive part of the present disclosure. The metal member may be supported on the second conductive part 32B, for example.

Each of the first semiconductor elements 10A and the second semiconductor elements 10B includes a first obverse-surface electrode 11, a second obverse-surface electrode 12, a third obverse-surface electrode 13, and a reverse-surface electrode 15. The description given below of the first obverse-surface electrode 11, the second obverse-surface electrode 12, the third obverse-surface electrode 13, and the reverse-surface electrode 15 is common to all the first semiconductor elements 10A and the second semiconductor elements 10B. The first obverse-surface electrode 11, the second obverse-surface electrode 12, and the third obverse-surface electrode 13 are disposed on the element obverse surface 101. The first obverse-surface electrode 11, the second obverse-surface electrode 12, and the third obverse-surface electrode 13 are insulated by an insulating film not shown in the figures. The reverse-surface electrode 15 is disposed on the element reverse surface 102.

The first obverse-surface electrode 11 is a gate electrode, for example, and receives a drive signal (e.g., gate voltage) inputted to drive the first semiconductor element 10A (the second semiconductor element 10B). The electrode 12 of the first second obverse-surface semiconductor element 10A (the second semiconductor element 10B) is a source electrode, for example, and conducts the source current. The second obverse-surface electrode 12 of the present embodiment includes a gate finger 121. In one example, the gate finger 121 is a linear insulator that extends in the x direction and divides the second obverse-surface electrode 12 into two regions in the y direction. The third obverse-surface 13 electrode is a source-sense electrode, for example, and conducts the source current. The reverse-surface electrode 15 is a drain electrode, for example, and conducts the drain current. The reverse-surface electrode 15 covers substantially the entire region of the element reverse surface 102. The reverse-surface electrode 15 may be composed of a silver (Ag) plating, for example.

Each first semiconductor element 10A (each second semiconductor element 10B) switches between a conducting state and a non-conducting state in response to a drive signal (gate voltage) inputted to the first obverse-surface electrode 11 (the gate electrode). In the conducting state, the current flows from the reverse-surface electrode 15 (the drain electrode) to the second obverse-surface electrode 12 (the source electrode). In the non-conducting state, such electric current does not flow. In short, each first semiconductor element 10A (each second semiconductor element 10B) performs a switching operation. With the switching functions of the first semiconductor elements 10A and the second semiconductor elements 10B, the semiconductor device A1 converts the DC voltage applied between the fourth terminal 44 and each of the first terminal 41 and the second terminal 42 into AC voltage, for example. The semiconductor device A1 then outputs the resulting AC voltage from the third terminals 43.

The semiconductor device A1 includes thermistors 17 as shown in FIGS. 5, 8, and 9 in particular. The thermistors 17 are used as temperature sensors. The semiconductor device A1 may include temperature-sensing diodes in addition to, or in alternative to the thermistors 17.

The supporting substrate 3 supports the first semiconductor elements 10A and the second semiconductor elements 10B. The specific configuration of the supporting substrate 3 is not limited. For example, the supporting substrate 3 may be composed of a direct bonded copper (DBC) substrate or an active metal brazing (AMB) substrate. The supporting substrate 3 includes an insulating layer 31, a first metal layer 32, and a reverse-surface metal layer 33. The first metal layer 32 includes the first conductive part 32A and the second conductive part 32B. In one example, the supporting substrate 3 has a z-direction dimension of at least 0.4 mm and at most 3.0 mm.

The insulating layer 31 is made of a ceramic material with excellent thermal conductivity. Examples of such a ceramic material include silicon nitride (SiN). The insulating layer 31 is not limited to a ceramic material and may be an insulating resin sheet, for example. The insulating layer 31 is rectangular in plan view, for example. In one example, the insulating layer 31 has a z-direction dimension of at least 0.05 mm and at most 1.0 mm.

The first conductive part 32A supports the first semiconductor elements 10A, and the second conductive part 32B supports the second semiconductor elements 10B. The first conductive part 32A and the second conductive part 32B are formed on the upper surface (the surface facing the z1 side in the z direction) of the insulating layer 31. The first conductive part 32A and the second conductive part 32B are made of a material containing copper (Cu), for example. The material may contain other substances, such as aluminum (Al). The first conductive part 32A and the second conductive part 32B are spaced apart in the x direction. The first conductive part 32A is located on the x1 side in the x direction from the second conductive part 32B. Each of the first conductive part 32A and the second conductive part 32B is rectangular in plan view, for example. The first conductive part 32A and the second conductive part 32B, together with the first conductive member 5 and the second conductive member 6, form the path of the main circuit current that is switched by the first semiconductor elements 10A and the second semiconductor elements 10B.

The first conductive part 32A has a first obverse surface 301A. The first obverse surface 301A is a flat plane facing the z1 side in the z direction. The first semiconductor elements 10A are bonded to the first obverse surface 301A of the first conductive part 32A via the conductive bonding material 19. The second conductive part 32B has a second obverse surface 301B. The second obverse surface 301B is a flat plane facing the z1 side in the z direction. The second semiconductor elements 10B are bonded to the second obverse surface 301B of the second conductive part 32B via the conductive bonding material 19. The conductive bonding material 19 is not limited to a specific material, and examples include solder, metal paste, and sintered metal.

Each of the first conductive part 32A and the second conductive part 32B has a z-direction dimension of at least 0.1 mm and at most 1.5 mm, for example.

The reverse-surface metal layer 33 is formed on the lower surface (the surface facing the z2 side in the z direction) of the insulating layer 31. The reverse-surface metal layer 33 is made of the same material as that of a first metal layer 32. The reverse-surface metal layer 33 has a reverse surface 302. The reverse surface 302 is a flat plane facing the z2 side in the z direction. In the example shown in FIG. 11, the reverse surface 302 is exposed from the sealing resin 8, for example. The reverse surface 302 is available for attachment of a component, such as a heat dissipating member (such as a heat sink), which is not shown in the figure. In another example, the reverse surface 302 may be covered with the sealing resin 8, instead of being exposed from the sealing resin 8. In plan view, the reverse-surface metal layer 33 overlaps with both the first conductive part 32A and the second conductive part 32B.

The first terminal 41, the second terminal 42, the third terminals 43, and the fourth terminal 44 are made with metal plates. The metal plates may contain copper (Cu) or an alloy of copper (Cu), for example. In the example shown in FIGS. 1 to 5, 8, 9, and 11, the semiconductor device A1 includes one first terminal 41, one second terminal 42, one fourth terminal 44, and two third terminals 43, but the numbers of the respective terminals are not specifically limited.

The first terminal 41, the second terminal 42, and the fourth terminal 44 are input terminals for DC voltage that is to be converted. The fourth terminal 44 is a positive electrode (P terminal), and the first terminal 41 and the second terminal 42 are negative electrodes (N terminals). The third terminals 43 are output terminals for the AC voltage converted by the first semiconductor elements 10A and the second semiconductor elements 10B. The first terminal 41, the second terminal 42, the third terminals 43, and the fourth terminal 44 each have a portion covered with the sealing resin 8 and a portion exposed from the sealing resin 8.

As shown in FIG. 13, the fourth terminal 44 is electrically bonded to the first conductive part 32A. The method of electrical bonding is not limited and may be include options such as ultrasonic bonding, laser bonding, welding, or bonding via, for example, solder, metal paste or a sintered silver. As shown in FIGS. 8 and 9 in particular, the fourth terminal 44 is located on the x1 side in the x direction from the first semiconductor elements 10A and the first conductive part 32A. The fourth terminal 44 is electrically connected to the first conductive part 32A, and also to the reverse-surface electrodes 15 (the drain electrodes) of the first semiconductor elements 10A via the first conductive part 32A. The first terminal 41 and the second terminal 42 are electrically connected to the second conductive member 6. In the present embodiment, the first terminal 41 and the second conductive member 6 are integrally formed. The first terminal 41 and the second conductive member 6 that are integrally formed have no bonding material or joints, and they may be formed from a single metal plate by cutting, bending, and other processing. In the present embodiment, the second terminal 42 and the second conductive member 6 are also integrally formed. As long as the first terminal 41 and the second terminal 42 are electrically connected to the second conductive member 6, they may be separate components that are bonded together and thus have a joint. As shown in FIGS. 5 and 8 in particular, the first terminal 41 and the second terminal 42 are located on the x1 side in the x direction from the first semiconductor elements 10A and the first conductive part 32A. The first terminal 41 and the second terminal 42 are electrically connected to the second conductive member 6, and also to the second obverse-surface electrodes 12 (the source electrodes) of the respective second semiconductor elements 10B via the second conductive member 6.

As shown in FIGS. 1 to 5, and 11, the first terminal 41, the second terminal 42, and the fourth terminal 44 of the semiconductor device A1 protrude from the sealing resin 8 toward the x1 side in the x direction. The first terminal 41, the second terminal 42, and the fourth terminal 44 are spaced apart from each other. The first terminal 41 and the second terminal 42 are located opposite to each other across the fourth terminal 44 in the y direction. The first terminal 41 is located on the y1 side in the y direction from the fourth terminal 44, and the second terminal 42 is located on the y2 side in the y direction from the fourth terminal 44. The first terminal 41, the second terminal 42, and the fourth terminal 44 overlap with each other as viewed in the y direction.

As can be seen from FIGS. 8, 9, and 12, the two third terminals 43 are electrically bonded to the second conductive part 32B. The method of electrical bonding is not limited and may be include options such as ultrasonic bonding, laser bonding, welding, or bonding via, for example, solder, metal paste or a sintered silver. As shown in FIG. 8 in particular, the two third terminals 43 are located on the x2 side in the x direction from the second semiconductor elements 10B and the second conductive part 32B. The third terminals 43 are electrically connected to the second conductive part 32B, and also to the reverse-surface electrodes 15 (the drain electrodes) of the second semiconductor elements 10B via the second conductive part 32B. Note that the number of the third terminals 43 is not limited to two. For example, one third terminal 43 may be provided, or three or more third terminals 43 may be provided. In the case where one third terminal 43 is provided, it is preferably connected to the central portion of the second conductive part 32B in the y direction.

The control terminals 45 are pin-like terminals for controlling the first semiconductor elements 10A and the second semiconductor elements 10B. The control terminals 45 include a plurality of first control terminals 46A to 46E and a plurality of second control terminals 47A to 47D. The first control terminals 46A to 46E are used, for example, to control the first semiconductor elements 10A. The second control terminals 47A to 47D are used, for example, to control the second semiconductor elements 10B.

The first control terminals 46A to 46E are spaced apart in the y direction. As shown in FIGS. 8, 13, and 20 in particular, the first control terminals 46A to 46E are supported on the first conductive part 32A via the control terminal support 48 (a first support part 48A described later). As shown in FIGS. 5 and 8, the first control terminals 46A to 46E are located between the plurality of first semiconductor elements 10A and the first, second, and fourth terminals 41, 42, and 44 in the x direction.

The first control terminal 46A is a terminal for receiving input of a drive signal for the first semiconductor elements 10A (a gate terminal). The first control terminal 46A receives a drive signal (e.g., gate voltage) for driving the first semiconductor elements 10A.

The first control terminal 46B is a terminal for sensing the source signal of the first semiconductor elements 10A (a source sense terminal). The voltage applied to the second obverse-surface electrodes 12 (the source electrodes) of the first semiconductor elements 10A (the voltage corresponding to the source current) is detected at the first control terminal 46B.

The first control terminals 46C and 46D are electrically connected to a thermistor 17.

The first control terminal 46E is a terminal for sensing the drain signal of the first semiconductor elements 10A (a drain-sense terminal). The voltage applied to the reverse-surface electrodes 15 (the drain electrodes) of the first semiconductor elements 10A (the voltage corresponding to the drain current) is detected at the first control terminal 46E.

The second control terminals 47A to 47D are spaced apart in the y direction. As shown in FIGS. 8 and 13 in particular, the second control terminals 47A to 47D are supported on the second conductive part 32B via the control terminal support 48 (a second support part 48B described later). As shown in FIGS. 5 and 8, the second control terminals 47A to 47D are located between the second semiconductor elements 10B and the two third terminals 43 in the x direction.

The second control terminal 47A is a terminal for receiving input of a drive signal for the second semiconductor elements 10B (a gate terminal). The second control terminal 47A receives a drive signal (e.g., gate voltage) for driving the second semiconductor elements 10B. The second control terminal 47B is a terminal for sensing the source signal of the second semiconductor elements 10B (a source sense terminal). The voltage applied to the second obverse-surface electrodes 12 (the source electrodes) of the second semiconductor elements 10B (the voltage corresponding to the source current) is detected at the second control terminal 47B. The second control terminals 47C and 47D are electrically connected to a thermistor 17.

Each of the control terminals 45 (the first control terminals 46A to 46E and the second control terminals 47A to 47D) includes a holder 451 and a metal pin 452.

The holder 451 is made of a conductive material. As shown in FIGS. 14 and 15, the holder 451 is bonded to the control terminal support 48 (a first metal layer 482 described later) via a conductive bonding material 459. The holder 451 includes a tubular part, an upper flange, and a lower flange.

The upper flange extends from the upper end of the tubular part, and the lower flange extends from the lower end. The metal pin 452 is inserted into the holder 451, extending at least from the upper flange to the tubular part. The holder 451 is covered with the sealing resin 8 (a second projection 852 described later).

The metal pin 452 is a rod-like member extending in the z direction. The metal pin 452 is pressed into the holder 451 and supported by the holder 451. The metal pin 452 is electrically connected to the control terminal support 48 (the first metal layer 482 described later) at least through the holder 451. When the lower end (the end on the z2 side in the z direction) of the metal pin 452 is in contact with the conductive bonding material 459 within the insertion hole of the holder 451 as in the example shown in FIGS. 14 and 15, the electrical connection of the metal pin 452 to the control terminal support 48 is established also through the conductive bonding material 459.

The control terminal support 48 supports the control terminals 45. In the z direction, the control terminal support 48 is located between the first and second obverse surfaces 301A and 301B and the plurality of control terminals 45.

The control terminal support 48 includes a first support part 48A and a second support part 48B. The first support part 48A is disposed on the first conductive part 32A and supports the first control terminals 46A to 46E out of the plurality of control terminals 45. As shown in FIG. 14, the first support part 48A is bonded to the first conductive part 32A via a bonding material 49. The bonding material 49 can either be conductive or insulating, and solder is used in one example. The second support part 48B is disposed on the second conductive part 32B and supports the second control terminals 47A to 47D out of the plurality of control terminals 45. As shown in FIG. 15, the second support part 48B is bonded to the second conductive part 32B via the bonding material 49.

The control terminal support 48 (each of the first support part 48A and the second support part 48B) may be made with a direct bonded copper (DBC) substrate, for example. The control terminal support 48 includes a stack of an insulating layer 481, a first metal layer 482, and a second metal layer 483.

The insulating layer 481 is made of a ceramic material, for example. The insulating layer 481 is rectangular in plan view, for example.

As shown in FIGS. 14 and 15 in particular, the first metal layer 482 is formed on the upper surface of the insulating layer 481. Each control terminal 45 stands on the first metal layer 482. The first metal layer 482 is made of copper (Cu) or an alloy of copper (Cu), for example. As shown in FIG. 8 in particular, the first metal layer 482 includes a first segment 482A, a second segment 482B, a third segment 482C, a fourth segment 482D, a fifth segment 482E, and a sixth segment 482F. The first segment 482A, the second segment 482B, the third segment 482C, the fourth segment 482D, the fifth segment 482E, and the sixth segment 482F are spaced apart and insulated from each other.

A plurality of wires 71 are bonded to the first segment 482A. The wires 71 electrically connect the first segment 482A to the first obverse-surface electrodes 11 (the gate electrodes) of the first semiconductor elements 10A (the second semiconductor elements 10B). A plurality of wires 73 are bonded to the first segment 482A and the sixth segment 482F. Thus, the sixth segment 482F is electrically connected to the first obverse-surface electrodes 11 (the gate electrodes) of the first semiconductor elements 10A (the second semiconductor elements 10B) via the wires 73 and 71. As shown in FIG. 8, the first control terminal 46A is bonded to the sixth segment 482F of the first support part 48A, and the second control terminal 47A is bonded to the sixth segment 482F of the second support part 48B.

A plurality of wires 72 are bonded to the second segment 482B. The wires 72 electrically connects the second segment 482B to the third obverse-surface electrodes 13 (the source-sense electrodes) of the first semiconductor elements 10A (the second semiconductor elements 10). As shown in FIG. 8, the first control terminal 46B is bonded to the second segment 482B of the first support part 48A, and the second control terminal 47B is bonded to the second segment 482B of the second support part 48B.

A thermistor 17 is bonded to the third segment 482C and the fourth segment 482D. As shown in FIG. 8, the first control terminals 46C and 46D are respectively bonded to the third segment 482C and the fourth segment 482D of the first support part 48A. In addition, the second control terminals 47C and 47D are respectively bonded to the third segment 482C and the fourth segment 482D of the second support part 48B.

A wire 74 is bonded to the fifth segment 482E of the first support part 48A. The wire 74 electrically connects the fifth segment 482E to the first conductive part 32A. As shown in FIG. 8, the first control terminal 46E is bonded to the fifth segment 482E of the first support part 48A. The fifth segment 482E of the second support part 48B is not electrically connected to any part or component. The wires 71 to 74 mentioned above are bonding wires, for example. The wires 71 to 74 are made of a material containing gold (Au), A1 or copper (Cu), for example.

As shown in FIGS. 14 and 15 in particular, the second metal layer 483 is formed on the lower surface of the insulating layer 481. As shown in FIG. 14, the second metal layer 483 of the first support part 48A is bonded to the first conductive part 32A via the bonding material 49. As shown in FIG. 15, the second metal layer 483 of the second support part 48B is bonded to the second conductive part 32B via the bonding material 49.

The first conductive member 5 and the second conductive member 6, together with the first conductive part 32A and the second conductive part 32B, form the path of the main circuit current that is switched by the first semiconductor elements 10A and the second semiconductor elements 10B. The first conductive member 5 and the second conductive member 6 are spaced apart from the first obverse surface 301A and the second obverse surface 301B toward the z1 side in the z direction. In plan view, the first conductive member 5 and the second conductive member 6 overlap with the first obverse surface 301A and the second obverse surface 301B. In the present embodiment, each of the first conductive member 5 and the second conductive member 6 is made with a metal plate, and the metal contains copper (Cu) or an alloy of copper (Cu), for example. Specifically, the first conductive member 5 and the second conductive member 6 are metal plates having been bent as needed.

The first conductive member 5 is connected to the second obverse-surface electrodes 12 (the source electrodes) of the first semiconductor elements 10A and to the second conductive part 32B, thereby establishing an electrical connection between the second obverse-surface electrodes 12 of the first semiconductor elements 10A and the second conductive part 32B. The first conductive member 5 forms the path of the main circuit current that is switched by the first semiconductor elements 10A. As shown in FIGS. 7 and 8, the first conductive member 5 includes a main part 51, a plurality of first bonding parts 52, and a plurality of second bonding parts 53.

The main part 51 is located between the first semiconductor elements 10A and the second conductive part 32B in the x direction and has the shape of a strip extending in the y direction in plan view. The main part 51 overlaps with both the first conductive part 32A and the second conductive part 32B in plan view and is spaced apart from the first obverse surface 301A and the second obverse surface 301B toward the z1 side in the z direction. As shown in FIG. 16 in particular, the main part 51 is located on the z2 side in the z direction from a plurality of third path parts 66 and a fourth path part 67 of the second conductive member 6 described later and is closer than the third path parts 66 and the fourth path part 67 to the first obverse surface 301A and the second obverse surface 301B.

In the present embodiment, the main part 51 is parallel (or substantially parallel) to the first obverse surface 301A and the second obverse surface 301B.

As shown in FIG. 8 in particular, the main part 51 extends in the y direction to cover a region in which the first semiconductor elements 10A are positioned. As shown in FIGS. 7, 8, and 13 in particular, the main part 51 has a plurality of first openings 514. The first openings 514 may be through-holes extending in the z direction (the direction of the plate thickness of the main part 51), for example. The first openings 514 are spaced apart in the y direction. The first opening 514 are provided for the respective first semiconductor elements 10A. In the present embodiment, the main part 51 has four first openings 514, each of which corresponds in position in the y direction to one of the plurality of (four) first semiconductor elements 10A.

As shown in FIGS. 8 and 13 in particular, the first openings 514 of the present embodiment overlap with the space between the first conductive part 32A and the second conductive part 32B in plan view. The first openings 514 are provided to facilitate the flow of a molten resin material between the upper region (on the z1 side in the z direction) and the lower region (on the z2 side in the z direction) around the main part 51 (the first conductive member 5) when the molten resin material is injected in the process of forming the sealing resin 8.

As shown in FIG. 8 in particular, the first bonding parts 52 and the second bonding parts 53 extend from the main part 51 at positions corresponding to the first semiconductor elements 10A. Specifically, the first bonding parts 52 are located on the x1 side of the main part 51 in the x direction. The second bonding parts 53 are located on the x2 side of the main part 51 in the x direction. As shown in FIG. 14, each first bonding part 52 is bonded to the second obverse-surface electrode 12 of a corresponding first semiconductor element 10A via a conductive bonding material 59. Each second bonding part 53 is bonded to the second conductive part 32B via the conductive bonding material 59. The conductive bonding material 59 is not limited to a specific material, and examples include solder, metal paste, and sintered metal. In the present embodiment, each first bonding part 52 includes two regions separated in the y direction by the gate finger 121 of the second obverse-surface electrode 12 of a corresponding first semiconductor element 10A. The two regions are bonded to the second obverse-surface electrode 12.

The second conductive member 6 electrically connects the second obverse-surface electrodes 12 (the source electrodes) of the second semiconductor elements 10B to the first terminal 41 and the second terminal 42. The second conductive member 6 is integrally formed with the first terminal 41 and the second terminal 42. The second conductive member 6 forms the path of the main circuit current that is switched by the second semiconductor elements 10B. As shown in FIGS. 7, and 21 to 25, the second conductive member 6 includes a plurality of third bonding parts 61, a first path part 64, a second path part 65, a plurality of third path parts 66, and a fourth path part 67. In the illustrated example, in addition, the second conductive member 6 includes a first ramp part 602 and a second ramp part 603.

The third bonding parts 61 are bonded to the respective second semiconductor elements 10B. Each third bonding part 61 is bonded to the second obverse-surface electrode 12 of a corresponding second semiconductor element 10B via a conductive bonding material 69. The conductive bonding material 69 is not limited to a specific material, and examples include solder, metal paste, and sintered metal. In the present embodiment, each third bonding part 61 includes two flat sections 611 and two first inclined sections 612.

The two flat sections 611 are aligned in the y direction. The two flat sections 611 are spaced apart from each other in the y direction. The shape of the flat sections 611 is not specifically limited. In the illustrated example, the flat sections 611 are rectangular. The two flat sections are bonded to the second obverse-surface electrode 12 of a corresponding second semiconductor element 10B at locations on the opposite sides of the gate finger 121 in the y direction.

The two first inclined sections 612 are connected to the outer ends of the respective two flat sections 611 in the y direction. That is, the first inclined section 612 that is located on the y1 side in the y direction is connected to the y1-side end of the flat section 611 that is located on the y1 side in the y direction. The first inclined section 612 that is located on the y2 side in the y direction is connected to the y2-side end of the flat section 611 that is located on the y2 side in the y direction. Each first inclined section 612 is inclined toward the z1 side in the z direction with an increasing distance from the flat section 611 in the y direction.

The first path part 64 is located between the third bonding parts 61 and the first terminal 41. In the illustrated example, the first path part 64 is connected to the first terminal 41 via the first ramp part 602. The first path part 64 overlaps with the first conductive part 32A in plan view. The first path part 64 generally extends in the x direction.

The first path part 64 includes a first band-shaped section 641 and a first extended section 643. The first band-shaped section 641 is located on the x2 side in the x direction from the first terminal 41 and is substantially parallel to the first obverse surface 301A. The first band-shaped section 641 generally extends in the x direction. In the illustrated example, the first band-shaped section 641 has a recess 649. The recess 649 is a portion of the first band-shaped section 641 that is recessed toward the y1 side in the y direction. In FIG. 5, a first metal part 35 is visible through the recess 649.

The first extended section 643 extends from the end on the y1 side in the y direction of the first band-shaped section 641 toward the z2 side in the z direction. The first extended section 643 is spaced apart from the first conductive part 32A. In the illustrated example, the first extended section 643 extends in the z direction and has a rectangular shape that is elongated in the x direction. Note that the first path part 64 may be configured without the first extended section 643.

The second path part 65 is located between the third bonding parts 61 and the second terminal 42. In the illustrated example, the second path part 65 is connected to the second terminal 42 via the second ramp part 603. The second path part 65 overlaps with the first conductive part 32A in plan view. The second path part 65 generally extends in the x direction.

The second path part 65 includes a second band-shaped section 651 and a second extended section 653. The second band-shaped section 651 is located on the x2 side in the x direction from the second terminal 42 and is substantially parallel to the first obverse surface 301A. The second band-shaped section 651 generally extends in the x direction. In the illustrated example, the second band-shaped section 651 has a recess 659. The recess 659 is a portion of the second band-shaped section 651 that is recessed toward the y2 side in the y direction. In FIG. 5, a second metal part 36 is visible through the recess 659.

The second extended section 653 extends from the end on the y2 side in the y direction of the second band-shaped section 651 toward the z2 side in the z direction. The second extended section 653 is spaced apart from the first conductive In the illustrated example, the second extended part 32A. section 653 extends in the z direction and has a rectangular shape that is elongated in the x direction. Note that the second path part 65 may be configured without the second extended section 653.

In the description given below, other configurations of the first path part 64 may be presented according to variations and other embodiments. Such configurations may also apply to the second path part 65, because the first path part 64 and the second path part 65 are symmetrical with respect to, for example, the centerline extending in the x direction.

The third path parts 66 are separately connected to the third bonding parts 61. The third path parts 66 extend in the x direction and spaced apart from each other in the y direction. The number of the third path parts 66 to be provided is not specifically limited. In the illustrated example, five third path parts 66 are provided. Each third path part 66 is located either between the second semiconductor elements 10B in the y direction or outside of the second semiconductor elements 10B in the y direction.

The two outermost third path parts 66 in the y direction are formed with recesses 669. Each recess 669 is recessed from the inner side toward the outer side in the y direction. In the illustrated example, each of the two outermost third path parts 66 has one recess 669. In FIG. 5, the second conductive part 32B is visible through the recesses 669.

In the present embodiment, each third bonding part 61 is located between two third path parts 66 adjacent in the y direction. Each third bonding part 61 has two first inclined sections 612, one on the y1 side in the y direction and the other on the y2 side. The first inclined section 612 on the y1 side is connected to one of the two adjacent third path parts 66 that is located on the y1 side in the y direction. The first inclined section 612 on the y2 side is connected to one of the two adjacent third path parts 66 that is on the y2 side in the y direction.

The fourth path part 67 is connected to the ends of the respective third path parts 66 on the x1 side in the x direction. The fourth path part 67 generally extends in the y direction. The fourth path part 67 is connected to the x2-side end of the first band-shaped section 641 of the first path part 64 and also to the x2-side end of the second band-shaped section 651 of the second path part 65. In the illustrated example, the fourth path part 67 is connected to the first path part 64 at the end on the y1 side in the y direction and to the second path part 65 at the end of the y2 side in the y direction.

In the present embodiment, the positions of the flat sections 611 of the third bonding parts 61 in the z direction are designed to conform to warping of the supporting substrate 3. Specifically, as shown in FIG. 23, the positions of the third path parts 66 in the z direction are uniform (or substantially uniform). In addition, the positions of the third path parts 66 and the fourth path part 67 in the z direction are also uniform (or substantially uniform). The distances Gz between the flat sections 611 of the third bonding parts 61 and a fifth bonding part 63 are designed to conform to warping of the supporting substrate 3.

With reference to FIG. 23, the distances Gz of the respective third bonding parts 61 in the order from the y2 side in the y direction are denoted as a distance Gz1, a distance Gz2, a distance Gz3, and a distance Gz4. The imaginary line in the figure represents the curve of the second obverse surface 301B of the supporting substrate 3 due to warping. Note that the curve is exaggerated for illustration purpose. In the illustrated example, the second obverse surface 301B is curved such that the middle portion in the y direction is closer toward the z2 side in the z direction, and the ends in the y direction are closer toward the z1 side in the z direction. In this example, the distance Gz1 is smaller than the distance Gz2, and the distance Gz4 is smaller than the distance Gz3. The distances Gz1 and Gz4 may be substantially the same, and the distances Gz2 and Gz3 may be substantially the same. The difference between the distances Gz1 and Gz2 is about 40 μm, for example. The difference between the distances Gz3 and Gz4 is about 40 μm, for example. The thickness of the conductive bonding material 69 may be about at least 60 μm and at most 120 μm, for example. Note that the size relation among the distances Gz1 and Gz4 is designed in consideration of the direction and magnitude of warping to occur in the supporting substrate 3 (the second obverse surface 301B).

As shown in FIG. 24, in the present embodiment, the thickness t2 of each first inclined section 612 is smaller than the thickness t1 of each flat section 611. In addition, the thickness t2 of each first inclined section 612 is smaller than the thickness to of each third path part 66. In addition, the thickness t1 of each flat section 611 is the same (or substantially the same) as the thickness to of each third path part 66.

The process of forming the third bonding parts 61 described above begins with cutting or other processes of a metal plate to form intermediate sections, which will be formed into the flat sections 611 and the first inclined sections 612. Note that two intermediate sections are formed into one third bonding part 61. The two intermediate portions are separated by a gap 619. The gap 619 serves as a space for placing a gate finger 121 of the second obverse-surface electrode 12 of a second semiconductor element 10B. Thus, the gap 619 is designed to be substantially equal to or slightly larger than the y-direction dimension of a gate finger 121.

Then, appropriate portions of the two intermediate sections, which will be formed into two flat sections 611, are clamped with a die or the like and moved toward the z2 side in the z direction relative to the third path parts 66 and the fourth path part 67. As a result, each of the two intermediate sections has an inclined portion, forming the two first inclined sections 612. In this process, the first inclined sections 612 are pulled, so that the thickness t2 is reduced to be smaller than thicknesses t1 and to. The y-direction dimension of the gap 619 remains virtually unchanged before and after the process of moving the die toward the z2 side in the z direction. The lengths of the distances Gz1 to Gz4 can be adjusted by, for example, changing the travel amount of the die.

The sealing resin 8 covers the first semiconductor elements 10A, the second semiconductor elements 10B, the supporting substrate 3 (except for the reverse surface 302), a portion of each of the first, second, third, and fourth terminals 41, 42, 43, and 44, a portion of each control terminal 45, the control terminal support 48, the first conductive member 5, the second conductive member 6, and the wires 71 to 74. The sealing resin 8 may be made of a black epoxy resin, for example. The sealing resin 8 may be formed by molding, for example. In one example, the sealing resin 8 has an x-direction dimension of about 35 to 60 mm, a y-direction dimension of about 35 to 50 mm, and a z-direction dimension of about 4 to 15 mm. These dimensions are measured at the largest portions in the respective directions. The sealing resin 8 has a resin obverse surface 81, a resin reverse surface 82, and resin side surfaces 831 to 834.

As shown in FIGS. 10, 12, and 18 in particular, the resin obverse surface 81 and the resin reverse surface 82 are spaced apart in the z direction. The resin obverse surface 81 faces the z1 side in the z direction, and the reverse surface 82 faces z2 side in the z direction. The control terminals 45 (the first control terminals 46A to 46E and the second control terminals 47A to 47D) protrude from the resin obverse surface 81. As shown in FIG. 11, the resin reverse surface 82 has the shape of a frame surrounding the reverse surface 302 (the lower surface of the reverse-surface metal layer 33) of the supporting substrate 3 in plan view. The reverse surface 302 of the supporting substrate 3 is exposed from the resin reverse surface 82 and is flush with the resin reverse surface 82, for example. The resin side surfaces 831 to 834 are connected to both the resin obverse surface 81 and the resin reverse surface 82 and are located between the resin obverse surface 81 and the resin reverse surface 82 in the z direction. As shown in FIG. 4 in particular, the resin side surfaces 831 and 832 are spaced apart in the x direction. The resin side surface 831 faces the x2 side in the x direction, and the resin side surface 832 faces the x1 side in the x direction. The two third terminals 43 protrude from the resin side surface 831, whereas the first terminal 41, the second terminal 42, and the fourth terminal 44 protrude from the resin side surface 832. As shown in FIG. 4 in particular, the resin side surfaces 833 and 834 are spaced apart in the y direction. The resin side surface 833 faces the y2 side in the y direction, and the resin side surface 834 faces the y1 side in the y direction.

As shown in FIG. 4, the resin side surface 832 has a plurality of recesses 832a. Each recess 832a is recessed in the x direction in plan view. The recesses 832a include one formed between the first terminal 41 and the fourth terminal 44, and one formed between the second terminal 42 and the fourth terminal 44. The recesses 832a are provided to increase the creepage distance along the resin side surface 832 between the first terminal 41 and the fourth terminal 44 and also between the second terminal 42 and the fourth terminal 44.

As shown in FIGS. 12 and 13 in particular, the sealing resin 8 includes a plurality of first projections 851, a plurality of second projections 852, and a resin cavity 86.

The first projections 851 protrude from the resin obverse surface 81 in the z direction. The first projections 851 are located near the four corners of the sealing resin 8 in plan view. Each first projection 851 has a first-projection end surface 851a at its end (the end on the z1 side in the z direction). The first-projection end surfaces 851a of the first projections 851 are substantially parallel to the resin obverse surface 81 and are contained in the same plane (x-y plane). Each first projection 851 has the shape of a hollow truncated cone with a bottom, for example. The first projections 851 serve as spacers when the semiconductor device A1 is mounted on, for example, a control circuit board of a device that operates on the power generated by the semiconductor device A1. Each first projection 851 has a recess 851b and an inner wall 851c of the recess 851b. Each first projection 851 is columnar, which preferably is a cylindrical column. The recess 851b has a cylindrical shape, preferably with the inner wall 851c defining a perfect circle in plan view.

The semiconductor device A1 may be mechanically fastened to the control circuit board or the like by screwing, for example. In such a case, each first projection 851 may be formed with an internal thread on the inner wall 851c of the recess 851b. For example, an insert nut may be inserted into the recess 851b of each first projection 851.

As shown in FIG. 13 in particular, the second projections 852 protrude from the resin obverse surface 81 in the z direction. The second projections 852 overlap with the control terminals 45 in plan view. The metal pin 452 of each control terminal 45 protrudes from a second projection 852. Each second projection 852 has the shape of a truncated cone. Each second projection 852 covers the holder 451 and a portion of the metal pin 452 of a control terminal 45.

Next, the following describes effects of the present embodiment.

The first terminal 41 and the second conductive member 6 are integrally formed. Unlike the configuration in which the first terminal 41 and the second conductive member 6 are bonded to each other, the semiconductor device A1 of this configuration can be manufactured without a bonding process. In addition, the semiconductor device A1 of this configuration can avoid a risk of cracking or delamination at a joint during operation. Therefore, the semiconductor device A1 can be manufactured with simplified processes and enhance operational reliability.

The second terminal 42 and the second conductive member 6 are integrally formed. Unlike the configuration in which the second terminal 42 and the second conductive member 6 are bonded to each other, the semiconductor device A1 of this configuration can be manufactured without a bonding process. In addition, the semiconductor device A1 of this configuration can avoid a risk of cracking or delamination at a joint during operation. Therefore, the semiconductor device A1 can be manufactured with simplified processes and enhance operational reliability.

The second conductive member 6 includes the first ramp part 602 connected to the first terminal 41. This configuration increases the rigidity of the connection between the second conductive member 6 and the first terminal 41.

The second conductive member 6 includes the second ramp part 603 connected to the second terminal 42. This configuration increases the rigidity y of the connection between the second conductive member 6 and the second terminal 42.

Each third bonding part 61 includes two flat sections 611 and two first inclined sections 612. The two first inclined sections 612 are connected to the outer ends of the two flat sections 611 in the y direction. This means that the current flowing through each second obverse-surface electrode 12 flows to both sides in the y direction through the flat sections 611 and the first inclined sections 612.

This prevents concentration of electric current flowing through the second obverse-surface electrodes 12 at one point.

The two flat sections 611 of each third bonding part 61 are spaced apart from each other in the y direction. This ensures that the electric current flows efficiently through both of the two flat sections 611 and both of the two first inclined sections 612, which is effective for preventing current concentration.

The two flat sections 611 of each third bonding part 61 are spaced apart from each other. This allows the gate finger 121 of a second obverse-surface electrode 12 to be placed between the two flat sections 611.

Each third bonding part 61 is provided between two third path parts 66 adjacent to each other in the y direction. This enables the distribution of the electric current flowing through the second obverse-surface electrode 12 of a second semiconductor element 10B to disperse into two third path parts 66.

The flat sections 611 of the third bonding parts 61 are configured such that their positions in the z direction correspond to warping of the supporting substrate 3 (the second obverse surface 301B). This configuration provides more uniform distances in the z direction from the flat sections 611 of the third bonding parts 61 to the second obverse-surface electrodes 12 of the second semiconductor elements 10B. This prevents the thickness of the conductive bonding material 69, which bonds the second obverse-surface electrode 12 of a second semiconductor element 10B to the flat sections 611 of a corresponding third bonding part 61, from becoming undesirably thinner. This consequently prevents cracking or delamination of the conductive bonding material 69. The present embodiment can therefore prevent the shortening of product life.

The flat sections 611 of the third bonding parts 61 are configured such that the distance Gz between each flat section 611 and a corresponding third path part 66 in the z direction correspond to warping of the supporting substrate 3 (the second obverse surface 301B). This configuration allows the third path parts 66 and the fourth path part 67 to be formed with flat shapes, for example, without consideration of warping of the supporting substrate 3. Consideration of warping of the supporting substrate 3 is necessary only in relation to the shapes of the third bonding parts 61.

The thickness t2 of each first inclined section 612 is smaller than the thickness t1 of each flat section 611. This configuration is achieved by applying a die pulling process as described above. Such a process facilitates forming the gap 619 to a desired size.

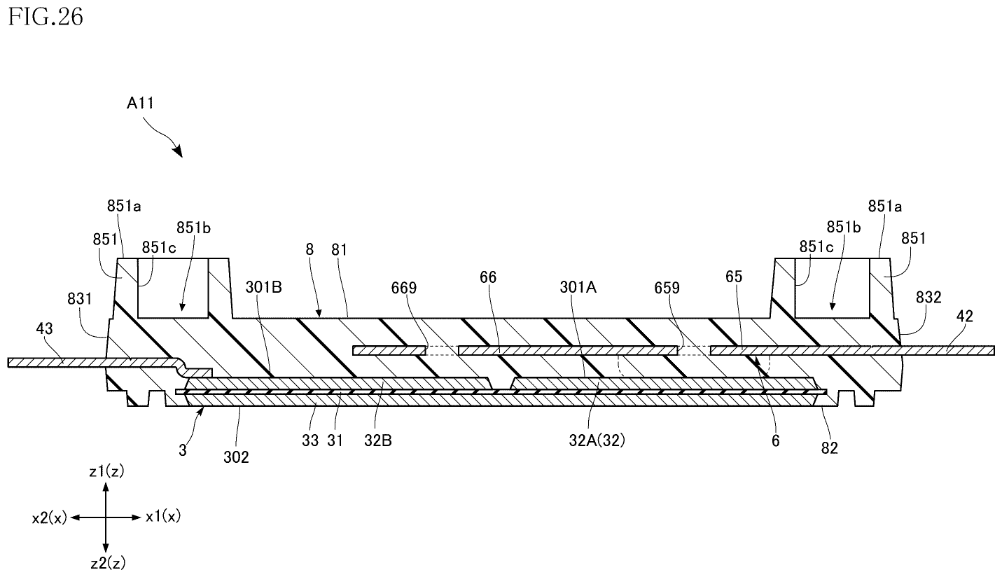

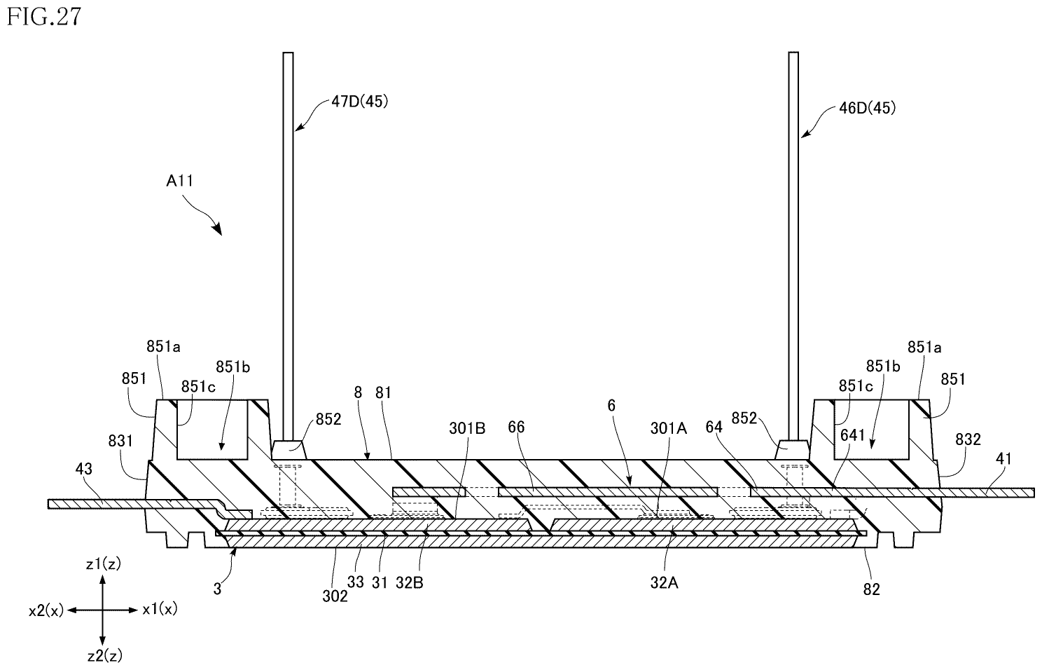

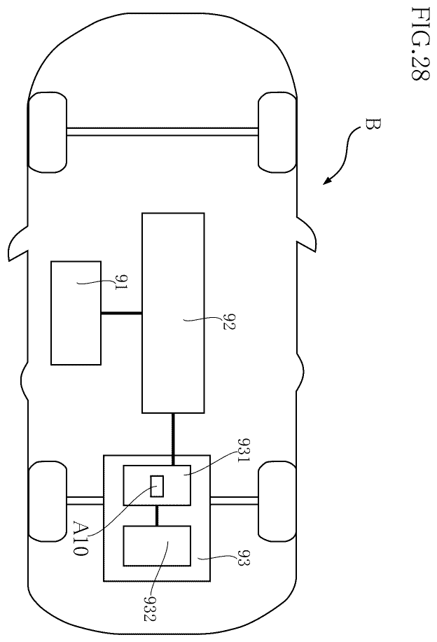

FIGS. 26 and 27 show variations of the present disclosure. In these figures, elements that are identical or similar to those described in the embodiment described above are indicated by the same reference numerals. In addition, the configuration of each part of any embodiment or variation can be combined in any way unless a technical contradiction arises. FIGS. 26 and 27 show a first variation of the semiconductor device A1. The semiconductor device A11 of this variation features that the second conductive member 6 does not include the first ramp part 602 and the second ramp part 603 described above.

In this variation, the position of the first terminal 41 in the z direction is the same (or substantially the same) as the position of the first band-shaped section 641 of the first path part 64 in the z direction. That is, the first terminal 41 and the first band-shaped section 641 are connected as one continuous flat plate.

Similarly, the position of the second terminal 42 in the z direction is the same (or substantially the same) as the position of the second band-shaped section 651 of the second path part 65 in the z direction. That is, the second terminal 42 and the second band-shaped section 651 are connected as one continuous flat plate.

Therefore, the semiconductor device A11 of this variation can be manufactured with simplified processes and enhance operational reliability. As can be understood from this variation, in addition, the shapes of the connection between the second conductive member 6 and each of the first terminal 41 and the second terminal 42 is not specifically limited.

Next, with reference to FIG. 28, a vehicle B with a semiconductor device A10 is described. The vehicle B is an electric vehicle (EV), for example.

As shown in FIG. 28, the vehicle B includes an on-board charger 91, a storage battery 92, and a drive system 93. The on-board charger 91 receives power wirelessly from an outdoor power supply facility (not shown). In a different example, the on-board charger 91 may be receive power from a power supply facility via wired connection. The on-board charger 91 includes a step-up DC-DC converter. The voltage supplied to the on-board charger 91 is boosted by the converter and then supplied to the storage battery 92. The voltage is boosted to 600 V, for example.

The drive system 93 is used to drive the vehicle B. The drive system 93 includes an inverter 931 and a drive source 932. The semiconductor device A10 constitutes a part of the inverter 931. The power stored on the storage battery 92 is supplied to the inverter 931. The power supplied from the storage battery 92 to the inverter 931 is DC power. In an example different from FIG. 24, the power system may additionally include a DC-DC converter between the storage battery 92 and the inverter 931. The inverter 931 converts the DC power into AC power. The inverter 931 that includes the semiconductor device A10 is electrically connected to the drive source 932. The drive source 932 include an AC motor and a transmission. The AC power converted by the inverter 931 is supplied to the drive source 932 to rotate the AC motor. The rotation of the AC motor is transmitted to the transmission. The transmission appropriately reduces the rotational speed transmitted from the AC motor and drives the drive shaft of the vehicle B. This drives the vehicle B. Driving the vehicle B requires regulating the rotational speed of the AC motor based on the amount of accelerator pedal operation and other information. The semiconductor device A10 included in the inverter 931 is necessary for outputting the AC power at frequencies appropriately adjusted to match the required rotational speed of the AC motor.

The semiconductor device according to the present disclosure is not limited to the embodiments described above. Various modifications in design may be made freely in the specific structure of each part of the semiconductor device according to the present disclosure. The present disclosure includes embodiments described in the flowing clauses.

### Clause 1.

A semiconductor device comprising:
a supporting substrate including:
   a first conductive part that includes a first obverse surface facing a first side in a thickness direction and is located on a first side in a first direction orthogonal to the thickness direction; and
   a second conductive part that includes a second obverse surface facing the first side in the thickness direction and is located on a second side in the first direction;
a plurality of first semiconductor elements mounted on the first conductive part and each having a switching function;
a plurality of second semiconductor elements mounted on the second conductive part and each having a switching function;
a first terminal protruding toward the first side in the first direction relative to the first conductive part;
a first conductive member electrically connecting the plurality of first semiconductor elements and the second conductive part;
a second conductive member electrically connecting the plurality of second semiconductor elements and the first conductive part; and
a sealing resin covering the plurality of first semiconductor elements, the plurality of second semiconductor elements, the first conductive member, the second conductive member, a portion of the supporting substrate, and a portion of the first terminal,
wherein the first terminal and the second conductive member are integrally formed.

### Clause 2.

The semiconductor device according to Clause 1, further comprising a second terminal protruding toward the first side in the first direction relative to the first conductive part, the second terminal being located on a second side in a second direction orthogonal to the thickness direction and the first direction relative to the first terminal, and
wherein the second terminal and the second conductive member are integrally formed.

### Clause 3.

The semiconductor device according to Clause 2, wherein the first conductive member includes a plurality of first bonding parts bonded to the plurality of first semiconductor elements and a second bonding part bonded to the second conductive part, and
the second conductive member includes a plurality of third bonding parts bonded to the plurality of second semiconductor elements, a first path part located between the plurality of third bonding parts and the first terminal, and a second path part located between the plurality of third bonding parts and the second terminal.

### Clause 4.

The semiconductor device according to Clause 3, wherein the second conductive member includes a first ramp part located between the first terminal and the first path part.

### Clause 5.

The semiconductor device according to Clause 4, wherein the second conductive member includes a second ramp part located between the second terminal and the second path part.

### Clause 6.

The semiconductor device according to Clause 3, wherein the first terminal and the first path part are located at a same position in the thickness direction.

### Clause 7.

The semiconductor device according to Clause 6, wherein the second terminal and the second path part are located at a same position in the thickness direction.

### Clause 8.

The semiconductor device according to any one of Clauses 3 to 7, wherein the first path part includes a first band-shaped section extending in the first direction and a first extended section extending from the first band-shaped section toward a second side in the thickness direction.

### Clause 9.

The semiconductor device according to Clause 8, wherein the second path part includes a second band-shaped section extending in the first direction and a second extended section extending from the second band-shaped section toward the second side in the thickness direction.

### Clause 10.

The semiconductor device according to any one of Clauses 3 to 9, wherein the second conductive member includes a plurality of third path parts each extending in the first direction, and a fourth path part extending in the second direction and connected to ends of the plurality of third path parts on the first side in the first direction, the first path part, and the second path part.

### Clause 11.

The semiconductor device according to Clause 10, wherein the third bonding parts include:
two flat sections each bonded to the second semiconductor elements and aligned in the second direction; and
two first inclined sections connected to outer ends of the two flat sections in the second direction.

### Clause 12.

The semiconductor device according to Clause 11, wherein the first inclined sections extend from the third path parts in the second direction as viewed in the thickness direction.

### Clause 13.

The semiconductor device according to Clause 12, wherein a thickness of the first inclined sections is equal to or less than a thickness of the flat sections.

### Clause 14.

The semiconductor device according to Clause 13, wherein the thickness of the first inclined sections is equal to or less than a thickness of the third path parts.

### Clause 15.

The semiconductor device according to Clause 14, wherein the thickness of the flat sections is equal to the thickness of the third path parts.

### Clause 16.

The semiconductor device according to any one of Clauses 10 to 15, wherein the first bonding parts include two flat sections each bonded to the first semiconductor elements and aligned in the second direction, and positions of the flat sections of at least either the first bonding parts or the third bonding parts in the thickness direction are designed to conform to warping of the supporting substrate.

### Clause 17.

The semiconductor device according to Clause 16, wherein the positions of the flat sections of the third bonding parts in the thickness direction are designed to conform to warping of the supporting substrate.

### Clause 18.

A vehicle comprising:
a drive source; and
a semiconductor device according to any one of Clauses 1 to 17,
wherein the semiconductor device is electrically connected to the drive source.

### REFERENCE NUMERALS

A1, A11: semiconductor device B: vehicle
3: supporting substrate 5: first conductive member
6: second conductive member 8: sealing resin
10A: first semiconductor element 10B: second semiconductor element
11: first obverse-surface electrode 12: second obverse-surface electrode
13: third obverse-surface electrode 15: reverse-surface electrode
17: thermistor 19: conductive bonding material
31: insulating layer 32: first metal layer
32A: first conductive part 32B: second conductive part
33: reverse-surface metal layer 35: first metal part
36: second metal part 41: first terminal
42: second terminal 43: third terminal
44: fourth terminal 45: control terminal
46A, 46B, 46C, 46D, 46E: first control terminal
47A, 47B, 47C, 47D: second control terminal
48: control terminal support
48A: first support part 48B: second support part
49: bonding material 51: main part
52: first bonding part 53: second bonding part
59: conductive bonding material 61: third bonding part
63: fifth bonding part 64: first path part
66: third path part 65: second path part
69: conductive bonding material 67: fourth path part
71, 72, 73, 74: wire 81: resin obverse surface
82: resin reverse surface 86: resin cavity
101: element obverse surface 102: element reverse surface
121: gate finger 301A: first obverse surface
301B: second obverse surface 302: reverse surface
451: holder 452: metal pin
481: insulating layer 459: conductive bonding material
482: first metal layer 482A: first segment
482B: second segment 482C: third segment
482D: fourth segment 482E: fifth segment
482F: sixth segment 483: second metal layer
514: first opening 602: first ramp part
603: second ramp part 611: flat section
612: first inclined section 619: gap
641: first band-shaped section 643: first extended section
649: recess 651: second band-shaped section
653: second extended section 659: recess
669: recess 831: resin side surface
832: resin side surface 832a: recess
833: resin side surface 834: resin side surface
851: first projection 851a: first-projection end surface
851b: recess 851c: inner wall
852: second projection 91: on-board charger
92: storage battery 93: drive system
931: inverter 932: drive source
Gz, Gz1, Gz2, Gz3, Gz4: distance
t0, t1, t2: thickness

1. A semiconductor device comprising:
a supporting substrate including:
a first conductive part that includes a first obverse surface facing a first side in a thickness direction and is located on a first side in a first direction orthogonal to the thickness direction; and
a second conductive part that includes a second obverse surface facing the first side in the thickness direction and is located on a second side in the first direction;
a plurality of first semiconductor elements mounted on the first conductive part and each having a switching function;
a plurality of second semiconductor elements mounted on the second conductive part and each having a switching function;
a first terminal protruding toward the first side in the first direction relative to the first conductive part;
a first conductive member electrically connecting the plurality of first semiconductor elements and the second conductive part;
a second conductive member electrically connecting the plurality of second semiconductor elements and the first conductive part; and
a sealing resin covering the plurality of first semiconductor elements, the plurality of second semiconductor elements, the first conductive member, the second conductive member, a portion of the supporting substrate, and a portion of the first terminal,
wherein the first terminal and the second conductive member are integrally formed.

2. The semiconductor device according to claim 1, further comprising a second terminal protruding toward the first side in the first direction relative to the first conductive part, the second terminal being located on a second side in a second direction orthogonal to the thickness direction and the first direction relative to the first terminal, and
wherein the second terminal and the second conductive member are integrally formed.

3. The semiconductor device according to claim 2, wherein the first conductive member includes a plurality of first bonding parts bonded to the plurality of first semiconductor elements and a second bonding part bonded to the second conductive part, and
the second conductive member includes a plurality of third bonding parts bonded to the plurality of second semiconductor elements, a first path part located between the plurality of third bonding parts and the first terminal, and a second path part located between the plurality of third bonding parts and the second terminal.

4. The semiconductor device according to claim 3, wherein the second conductive member includes a first ramp part located between the first terminal and the first path part.

5. The semiconductor device according to claim 4, wherein the second conductive member includes a second ramp part located between the second terminal and the second path part.

6. The semiconductor device according to claim 3, wherein the first terminal and the first path part are located at a same position in the thickness direction.

7. The semiconductor device according to claim 6, wherein the second terminal and the second path part are located at a same position in the thickness direction.

8. The semiconductor device according to claim 3, wherein the first path part includes a first band-shaped section extending in the first direction and a first extended section extending from the first band-shaped section toward a second side in the thickness direction.

9. The semiconductor device according to claim 8, wherein the second path part includes a second band-shaped section extending in the first direction and a second extended section extending from the second band-shaped section toward the second side in the thickness direction.

10. The semiconductor device according to claim 3, wherein the second conductive member each includes a plurality of third path parts each extending in the first direction, and a fourth path part extending in the second direction and connected to ends of the plurality of third path parts on the first side in the first direction, the first path part, and the second path part.

11. The semiconductor device according to claim 10, wherein the third bonding parts each include:
two flat sections each bonded to the second semiconductor elements and aligned in the second direction; and
two first inclined sections connected to outer ends of the two flat sections in the second direction.

12. The semiconductor device according to claim 11, wherein the first inclined sections each extend from the third path parts in the second direction as viewed in the thickness direction.

13. The semiconductor device according to claim 12, wherein a thickness of the first inclined sections is equal to or less than a thickness of the flat sections.

14. The semiconductor device according to claim 13, wherein the thickness of the first inclined sections is equal to or less than a thickness of the third path parts.

15. The semiconductor device according to claim 14, wherein the thickness of the flat sections is equal to the thickness of the third path parts.

16. The semiconductor device according to claim 10, wherein the first bonding parts each include two flat sections each bonded to the first semiconductor elements and aligned in the second direction, and
positions of the flat sections of at least either the first bonding parts or the third bonding parts in the thickness direction are designed to conform to warping of the supporting substrate.

17. The semiconductor device according to claim 16, wherein the positions of the flat sections of the third bonding parts in the thickness direction are designed to conform to warping of the supporting substrate.

18. A vehicle comprising:
a drive source; and
a semiconductor device according to claim 1,
wherein the semiconductor device is electrically connected to the drive source.
